(19) United States
(12) Patent Application Publication
(10) Pub. No.: US 2002/0173096 A1
(43) Pub. Date: Nov. 21, 2002

(54) Semiconductor integrated circuit and method of manufacturing same

(75) Inventor: Tomonori Okudaira, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MITSUBISHI DENKI KABUSHIKI KAISHA, Tokyo (JP)

(21) Appl. No.: 10/109,837

(22) Filed: Apr. 1, 2002

(30) Foreign Application Priority Data
May 21, 2001 (JP) 2001-150495

(51) Int. Cl. H01L 21/8242; H01L 27/108

(52) U.S. Cl. 438/253; 438/256; 438/396; 438/399; 438/640; 257/306; 257/308; 257/774

(57) ABSTRACT

In a semiconductor integrated circuit having improvement in integration, it is an object of the present invention to provide a structure ensuring a contact area between a contact plug and a conductive layer formed thereon and connected thereto, to thereby realize reduction in contact resistance. A plurality of bit lines (8) are selectively formed in an interlayer insulating film (9). Each of the bit lines (8) is connected to a predetermined impurity diffusion layer (2) through a contact plug (7). The upper surface of a contact plug (10) as an end opposite to the lower surface thereof protrudes from the main surface of the interlayer insulating film (9). On the contact plug (10), a capacitor lower electrode (11) is formed to cover the protruding part of the contact plug (10) in such a manner that the center of the capacitor lower electrode (11) is located at a position deviated from the center of the contact plug (10).

### BACKGROUND OF THE INVENTION

1. Field of the Invention

The present invention is directed to a semiconductor integrated circuit. More particularly, it is directed to reduction in contact resistance in the semiconductor integrated circuit having improvement in integration.

2. Description of the Background Art

In a capacitor having a high-dielectric film (high-dielectric film capacitor), the dielectric film tends to have a large thickness as compared with a dielectric film having a low dielectric constant such an SiON (oxynitride) film. The high-dielectric film capacitor included in a semiconductor integrated circuit has a high dielectric constant. Therefore, with the level of integration so far, the semiconductor integrated circuit including the high-dieletric film has been configured without the need to employ structures for enlarging area of the capacitor such as three-dimensional structure of a storage node electrode of the capacitor (capacitor lower electrode).

Accompanied by considerable improvement in integration in recent years, however, even the high-dielectric film capacitor has been necessitated to employ the lower electrode of three-dimensional structure. On the contrary, as compared with the dielectric film having a low dielectric constant such as the oxynitride film, it is difficult to form a high-dielectric film having a small thickness. Due to this, sufficient spaces among lower electrodes of the capacitor should be inevitably maintained.

It is required to arrange various types of wiring layers with small spaces thereamong. These wiring layers have becoming narrow to have respective line widths approximately the same as a diameter of a contact plug for forming a contact part.

Further, a structure stacking a plurality of contact plugs, which is known as a stacked via contact, has been in use for establishing connection between an upper wiring layer and a lower wiring layer.

Here, when a via hole of the contact plug is formed, the upper opening of the via holes is made larger than the lower opening thereof due to etching characteristics, for example. Therefore, the contact plug formed through the formation of the via hole to be arranged under a lower electrode and various types of wiring layers tend to have an area in the upper surface larger than the area in the lower surface thereof.

An example of a semiconductor integrated circuit in the background art having the foregoing structure is illustrated in FIG. 37 as a semiconductor integrated circuit 90.

As illustrated in FIG. 37, an interlayer insulating film 6 is formed on a silicon substrate 1. A plurality of contact plugs 7 (bit line contacts) penetrating through the interlayer insulating film 6 to reach the silicon substrate 1 are provided. The contact plugs 7 are made of a conductive material such as polysilicon.

On the interlayer insulating film 6, an interlayer insulating film 9 is formed for holding an interlayer insulating film 14 formed thereon. A plurality of contact plugs 10 (storage node contacts) penetrating through the interlayer insulating films 6 and 9 to reach the silicon substrate 1 and a contact plug 15 penetrating through the interlayer insulating films 9 and 14 to reach some of the contact plugs 7 are provided.

A plurality of impurity diffusion layers 2 acting as source/drain layers of MOS transistors are selectively formed in the main surface of the silicon substrate 1. The main surface of the silicon substrate 1 further includes a plurality of element isolation insulating films 3 selectively formed therein for electrically isolating among the MOS transistors and defining active regions including the impurity diffusion layers 2. Further, the respective lower surfaces of the contact plugs 7 and 10 are connected to the impurity diffusion layers 2.

Each of gate electrodes 5 is formed in the interlayer insulating film 6 at a position on the silicon substrate 1 defined between adjacent impurity diffusion layers 2. A gate insulating film 4 is formed between the gate electrode 5 and the silicon substrate 1.

A plurality of bit lines 8 selectively formed in the interlayer insulating film 9 are connected to the predetermined impurity diffusion layers 2 through the contact plugs 7.

The contact plug 15 penetrating through the interlayer insulating films 9, 14 and the contact plug 7 having connection to the contact plug 15 constitute a stacked via contact. The connection is also established between the stacked via contact and one of the impurity diffusion layers 2.

The upper surface of the contact plug 10 as an end opposite to the lower surface thereof is connected to a capacitor lower electrode 11 (storage node electrode) selectively formed on the interlayer insulating film 9. The capacitor lower electrode 11, a capacitor dielectric film 12 covering the capacitor lower electrode 11 and a capacitor upper electrode 13 covering the capacitor dielectric film 12 constitute a capacitor CP. As the capacitor dielectric film 12 is made of a high dielectric material such as BST (barium strontium titanate), it follows that the capacitor CP is a high-dielectric film capacitor.

A plurality of metal wires 16 having small spaces thereamong are selectively provided on the interlayer insulating film 14. The upper surface of the contact plug 15 is connected to some of the metal wires 16.

Other constituents such as a wiring layer and a passivation film are provided on the metal wires 16 to constitute the semiconductor integrated circuit 90. However, these constituents having little relevance to the present invention are omitted from drawings.

In each of regions X, Y, W and Z illustrated in FIG. 37, the contact plugs 7, 10 and 15 have respective diameters larger than the width dimensions of the conductive layers provided thereon (bit line 8, capacitor lower electrode 11, contact plug 15 and metal wire 16).

This is caused by from the fact that the width dimensions of the upper conductive layers are narrowed accompanied by the improvement in integration of the semiconductor integrated circuit and further from the characteristics resulting from formation of the contact plugs. The reduction in contact area between the upper surface of the contact plug and the conductive layer causes the problem of rise in contact resistance.

The conductive layer arranged on the contact plug has had such a shape in the background art that the upper surface of the contact plug is covered with the conductive layer. Therefore, efforts to reduce contact resistance have been made by arranging the contact plug in such a manner that the upper surface of the contact plug protrudes so that connection is further established between a side surface of the contact plug and the conductive layer.

Contrary to this, the semiconductor integrated circuit 90 illustrated in FIG. 37 includes the conductive layer provided over the contact plug having a small width dimension accompanied by the improvement in integration as described above. Therefore, considerable increase in contact area cannot be expected by merely protruding the upper surface of the contact plug.

### SUMMARY OF THE INVENTION

A first aspect of the present invention is directed to a semiconductor integrated circuit, comprising: a semiconductor substrate; an interlayer insulating film formed on the semiconductor substrate; a conductive layer formed on the interlayer insulating film; and a contact plug penetrating through the interlayer insulating film and having electrical connection to the conductive layer, wherein the contact plug protrudes from an upper main surface of the interlayer insulating film by a predetermined height, the conductive layer has a dimension in a first direction smaller than a cross-sectional dimension of an upper surface of the contact plug in the first direction and a dimension in a second direction perpendicular to the first direction larger than a cross-sectional dimension of the upper surface of the contact plug in the second direction, and the conductive layer is arranged in contact with the contact plug in such a manner that a center of the conductive layer in the dimension in the first direction is located at a position deviated from a center of the upper surface of the contact plug.

In the semiconductor integrated circuit according to a second aspect of the present invention, the conductive layer is arranged in such a manner that one edge of the conductive layer in the dimension in the first direction is located outside an edge of the upper surface of the contact plug.

In the semiconductor integrated circuit according to a third aspect of the present invention, the contact plug has a cylindrical shape, and the cross-sectional dimensions of the upper surface of the contact plug in the first and second directions are corresponding to a diameter of the contact plug.

In the semiconductor integrated circuit according to a fourth aspect of the present invention, the predetermined height of protrusion of the contact plug is 0.16 times or more the diameter of the upper surface of the contact plug.

In the semiconductor integrated circuit according to a fifth aspect of the present invention, an amount of deviation of the center of the conductive layer in the dimension in the first direction from the center of the upper surface of the contact plug is 0.5 times or less the diameter of the upper surface of the contact plug.

In the semiconductor integrated circuit according to a sixth aspect of the present invention, the interlayer insulating film includes a recessed portion of a predetermined depth provided in a periphery of the contact plug and having a shape conforming to a shape of the conductive layer in a plan view, the conductive layer is arranged in such a manner that a part of the conductive layer is inserted into the recessed portion, and the predetermined depth of the recessed portion is corresponding to the predetermined height of protrusion of the contact plug.

In the semiconductor integrated circuit according to a seventh aspect of the present invention, the conductive layer is a storage node electrode of a capacitor formed on the interlayer insulating film.

In the semiconductor integrated circuit according to an eighth aspect of the present invention, the storage node electrode is of a shape in a plan view including a constricted part having a diameter smaller than a diameter of a part other than the constricted part, and the storage node electrode is arranged in such a manner that the constricted part is located on the upper surface of the contact plug.

In the semiconductor integrated circuit according to a ninth aspect of the present invention, the conductive layer is a wiring layer provided on the interlayer insulating film.

In the semiconductor integrated circuit according to a tenth aspect of the present invention, the wiring layer is of a shape in a plan view having different width dimensions, and the wiring layer is arranged in such a manner that the upper surface of the contact plug holds a part of the wiring layer provided thereon having a width dimension smaller than the diameter of the upper surface of the contact plug.

An eleventh aspect of the present invention is directed to a semiconductor integrated circuit, comprising: a semiconductor substrate; an interlayer insulating film formed on the semiconductor substrate; and a lower contact plug and an upper contact plug vertically arranged in the interlayer insulating film and connected to each other, wherein a lower surface of the upper contact plug has a cross-sectional dimension in a first direction smaller than a cross-sectional dimension of an upper surface of the lower contact plug in the first direction, and a center of the lower surface of the upper contact plug is located at a position deviated from a center of the upper surface of the lower contact plug so that connection is established between a part of the upper contact plug and a side surface of the lower contact plug.

In the semiconductor integrated circuit according to a twelfth aspect of the present invention, each of the lower and upper contact plugs have a cylindrical shape, the cross-sectional dimension of the lower surface of the upper contact plug in the first direction and the cross-sectional dimension of the upper surface of the lower contact plug in the first direction are corresponding to respective diameters of the upper contact plug and the lower contact plug, and an amount of deviation of the center of the lower surface of the upper contact plug from the center of the upper surface of the lower contact plug is 0.5 times or less the diameter of the upper surface of the lower contact plug.

A thirteenth aspect of the present invention is directed to a method of manufacturing a semiconductor integrated circuit, comprising the steps of: (a) forming an interlayer insulating film on a semiconductor substrate; (b) forming a contact plug penetrating through the interlayer insulating film to reach the semiconductor substrate; (c) locating the contact plug so that the contact plug protrudes from an upper main surface of the interlayer insulating film by a predetermined height; and (d) forming a conductive layer on the contact plug having a dimension in a first direction smaller than a cross-sectional dimension of an upper surface of the contact plug in the first direction and a dimension in a second direction perpendicular to the first direction larger than a cross-sectional dimension of the upper surface of the contact plug in the second direction, wherein the step (d) further comprises the step of locating the conductive layer so that the conductive layer is in contact with the contact plug in such a manner that a center of the conductive layer in the dimension in the first direction is at a position deviated from a center of the upper surface of the contact plug.

In the method of manufacturing a semiconductor integrated circuit according to a fourteenth aspect of the present invention, the step (c) further comprises the step of making a depression in a periphery of the contact plug by a predetermined depth to form a recessed portion therein having a shape conforming to a shape of the conductive layer in a plan view, the step (d) further comprises the step of locating the conductive layer so that a part of the conductive layer is inserted into the recessed portion, and the predetermined depth of the recessed portion is corresponding to the predetermined height of protrusion of the contact plug.

According to the semiconductor integrated circuit of the first aspect of the present invention, the contact plug protrudes from the upper main surface of the interlayer insulating film by the predetermined height and the conductive layer has a dimension in the first direction smaller than the cross-sectional dimension of the upper surface of the contact plug in the first direction and a dimension in the second direction perpendicular to the first direction larger than the cross-sectional dimension of the upper surface of the contact plug in the second direction. Further, the conductive layer is arranged in contact with the contact plug in such a manner that the center of the conductive layer in the dimension in the first direction is located at a position deviated from the center of the upper surface of the contact plug by a predetermined amount. The connection is thereby established, at least in the second direction, between the conductive layer and the side surface of the contact plug. Therefore, even in the semiconductor integrated circuit having improvement in integration, the contact area between the conductive layer and the contact plug is increased, resulting in the reduction in contact resistance.

According to the semiconductor integrated circuit of the second aspect of the present invention, the connection is further established between the conductive layer and the side surface of the contact plug in the first direction. Therefore, the contact area between the conductive layer and the contact plug is increased to a higher degree, resulting the reduction in contact resistance to a larger extent.

According to the semiconductor integrated circuit of the third aspect of the present invention, the contact plug has a cylindrical shape. Therefore, the amount of deviation of the conductive layer is easily calculated.

According to the semiconductor integrated circuit of the fourth and fifth aspects of the present invention, the increase in contact area between the conductive layer and the contact plug is ensured.

According to the semiconductor integrated circuit of the sixth aspect of the present invention, the structure including the contact plug protruding from the upper main surface of the interlayer insulating film is obtained.

According to the semiconductor integrated circuit of the seventh aspect of the present invention, the particular structure allowing the increase in contact area between the storage node electrode of the capacitor and the contact plug is obtained.

According to the semiconductor integrated circuit of the eighth aspect of the present invention, in the configuration having the storage node electrode that includes the constricted part, the particular structure allowing the increase in contact area between the storage node electrode and the contact plug is obtained.

According to the semiconductor integrated circuit of the ninth aspect of the present invention, the particular structure allowing the increase in contact area between the wiring layer and the contact plug is obtained.

According to the semiconductor integrated circuit of the tenth aspect of the present invention, in the configuration including the wiring layer that has different width dimensions, the structure allowing the increase in contact area between the wiring layer and the contact plug is obtained.

According to the semiconductor integrated circuit of the eleventh aspect of the present invention, the lower surface of the upper contact plug has a cross-sectional dimension in the first direction smaller than the cross-sectional dimension of the upper surface of the lower contact plug in the first direction and the center of the lower surface of the upper contact plug is located at a position deviated from the center of the upper surface of the lower contact plug by a predetermined amount. The connection is thereby established between the part of the upper contact plug and the side surface of the lower contact plug. Therefore, even in the semiconductor integrated circuit having improvement in integration, the contact area between the upper contact plug and the lower contact plug is increased, resulting in the reduction in contact resistance.

According to the semiconductor integrated circuit of the twelfth aspect of the present invention, the increase in contact area between the upper contact plug and the lower contact plug is ensured.

According to the method of manufacturing the semiconductor integrated circuit of the thirteenth aspect of the present invention, the connection is established, at least in the second direction, between the conductive layer and the side surface of the contact plug. Therefore, even in the semiconductor integrated circuit having improvement in integration, the contact area between the conductive layer and the contact plug is increased, resulting in the reduction in contact resistance.

According to the method of manufacturing the semiconductor integrated circuit of the fourteenth aspect of the present invention, as the recessed portion is provided, the structure including the contact plug protruding from the upper main surface of the interlayer insulating film is obtained.

In a semiconductor integrated circuit having improvement in integration, it is therefore an object of the present invention to provide a structure ensuring a contact area between a contact plug and a conductive layer formed thereon and connected thereto, to thereby realize reduction in contact resistance.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 and 2 are views illustrating a concept of the present invention;

FIGS. 3, 4 and 5 are graphs showing variation in contact area accompanied by changes in dimension of a short side of a conductive layer and in protrusion height of a contact plug;

FIGS. 6 and 7 are sectional views illustrating a structure of a semiconductor integrated circuit according to a first preferred embodiment of the present invention;

FIG. 8 is a plan view illustrating the structure of the semiconductor integrated circuit according to the first preferred embodiment of the present invention;

FIG. 9 is sectional view illustrating a structure of a modification of the semiconductor integrated circuit according to the first preferred embodiment of the present invention;

FIGS. 10 to 17 are sectional views illustrating steps of manufacturing the semiconductor integrated circuit according to the first preferred embodiment of the present invention;

FIG. 18 is a plan view illustrating a modification of a storage node electrode;

FIGS. 19 and 20 are sectional views illustrating a structure of a semiconductor integrated circuit according to a second preferred embodiment of the present invention;

FIGS. 21 to 28 are sectional views illustrating steps of manufacturing the semiconductor integrated circuit according to the second preferred embodiment of the present invention;

FIG. 29 is a sectional view partially illustrating a structure of a modification of the semiconductor integrated circuit according to the second preferred embodiment of the present invention;

FIG. 30 is a plan view illustrating a modification of a bit line;

FIG. 31 is a sectional view illustrating a structure of a semiconductor integrated circuit according to a third preferred embodiment of the present invention;

FIG. 32 is a sectional view partially illustrating the structure of the semiconductor integrated circuit according to the third preferred embodiment of the present invention;

FIGS. 33 to 36 are sectional views illustrating steps of manufacturing the semiconductor integrated circuit according to the third preferred embodiment of the present invention; and

FIG. 37 is a sectional view illustrating a structure of a semiconductor integrated circuit in the background art.

### DESCRIPTION OF THE PREFERRED EMBODIMENTS

<Concept of the Present Invention>

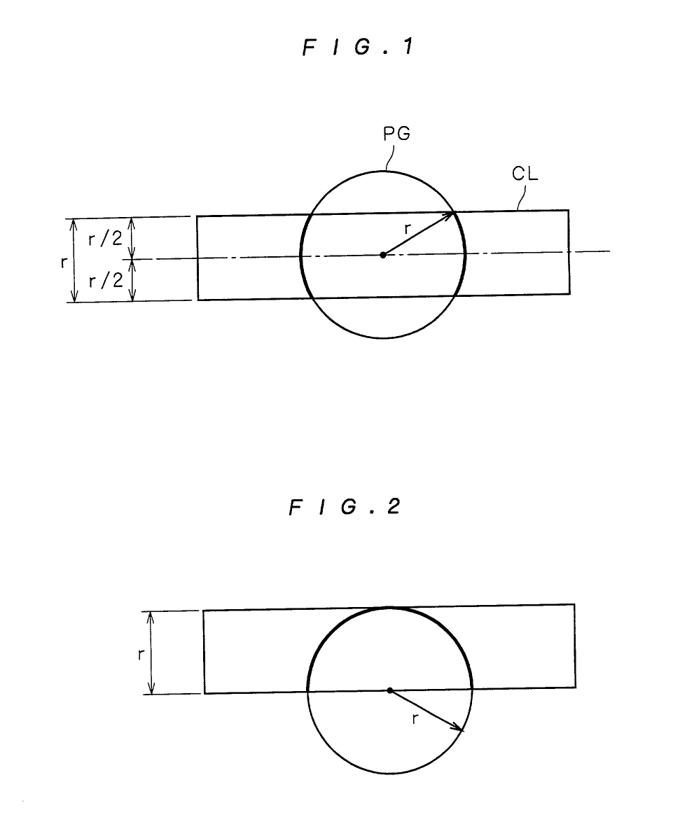

The concept of the present invention will be described in reference to FIGS. 1 and 2.

FIG. 1 is a view illustrating a contact plug PG and a conductive layer CL arranged on the contact plug PG at a proper position.

As illustrated in FIG. 1, the cylindrical-shaped contact plug PG has a circular shape on the upper surface and a radius of r. The dimension of a short side (hereinafter referred to as short side dimension) of the conductive layer CL is r as well. That is, the short side dimension of the conductive layer CL is half the diameter of the upper surface of the contact plug PG.

When the contact plug PG in the structure of FIG. 1 protrudes by a height h from the main surface of a layer in which the contact plug PG is buried, a contact area S1 between the contact plug PG and the conductive layer CL is expressed by the following equation (1):

S1=(π/3+\sqrt{3}/2)r²+(2/3)πrh (1)

This is the value of the contact area obtained by the protrusion of the contact plug in the semiconductor integrated circuit conventionally employed in the background art.

FIG. 2 is a view illustrating the concept of the present invention. In FIG. 2, the conductive layer CL is located at a position on the contact plug PG intentionally deviated by a distance r/2.

When the contact plug PG in the structure of FIG. 2 is arranged to protrude by the height h from the main surface of the layer in which the contact plug PG is buried, a contact area S2 between the contact plug PG and the conductive layer CL is expressed by the following equation (2):

S2=πr²/2+πrh (2)

Further, a difference S between the area S1 and the area S2 is expressed by the following equation (3):

S=r{(1/3)πh+(π/6−\sqrt{3}/2)r} (3)

When the protrusion height of the contact plug PG is approximately 0.16 times or more the diameter of the same, the relation of “S>0” is established. Hence, the reduction in contact resistance can be realized resulting from the increase in contact area.

When the short side dimension of the conductive layer is smaller than the diameter of the contact plug and connection is established between the side surface of the contact plug and the conductive layer, the conductive layer is so arranged that a center line thereof does not coincide with a center line of the conductive plug. An edge of a long side of the conductive layer is thereby moved to a position closer to an edge of the contact plug, to realize increase in contact area.

FIG. 2 illustrates an example in which the conductive layer CL is arranged in such a manner that the edge of the long side of the conductive layer CL marginally coincides with the edge of the contact plug PG. When it is not allowed to raise the protrusion height h of the contact plug PG, however, the conductive layer CL may be arranged in such a manner that the edge of the long side of the conductive layer CL is positioned outside the edge of the contact plug PG to ensure contact area. Conversely, when it is allowed to raise the protrusion height h of the contact plug PG to a sufficient extent, the conductive layer CL may be arranged in such a manner that the edge of the long side of the conductive layer CL is positioned inside the edge of the contact plug PG.

When it is not allowed to arrange the edge of the long side of the conductive layer CL to be outside the edge of the contact plug PG under layout constraints, the protrusion height h of the contact plug PG is defined to be half the diameter of the contact plug PG. The amount of deviation of the conductive layer CL is thereby defined to be 2/3 of the amount of deviation as illustrated in the example in FIG. 2.

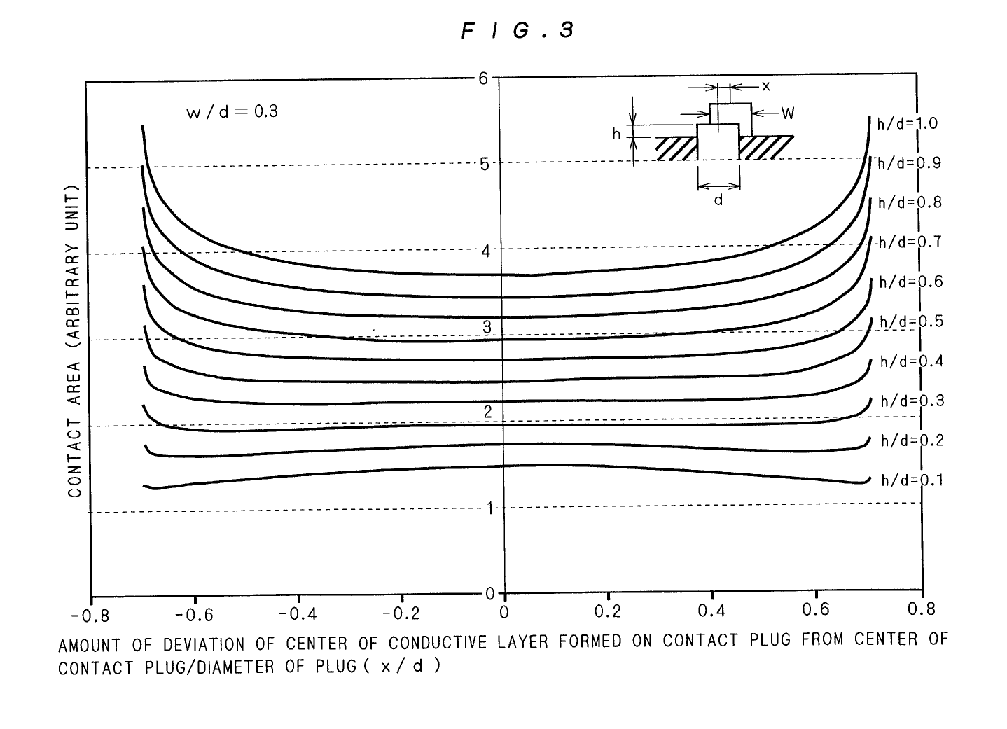

The variation in contact area accompanied by the change in short side dimension of the conductive layer formed on the contact plug and by the change in protrusion height of the contact plug will be described in reference to FIGS. 3, 4 and 5.

FIGS. 3, 4 and 5 are graphs showing the contact area between the conductive layer and the contact plug. In each example of FIGS. 3, 4 and 5, the short side dimension of the conductive layer is defined to be 0.3 times, 0.5 times and 0.7 times, respectively, the diameter of the upper surface of the contact plug. The variation in contact area shown in each graph of FIGS. 3, 4 and 5 is obtained by the change in ratio of the protrusion height of the contact plug to the diameter of the upper surface thereof.

Each horizontal axis of the graphs in FIGS. 3, 4 and 5 shows the ratio of the amount of deviation of the center of the conductive layer from the center of the contact plug to the diameter of the contact plug. Each vertical axis thereof shows contact area (arbitrary unit) between the conductive layer and the contact plug.

The diameter of the contact plug, the protrusion height thereof and the short side dimension of the conductive layer are represented as d, h and w, respectively. Further, the amount of deviation of the center of the conductive layer from the center of the contact plug is represented as x.

FIG. 3 shows the example in which the short side dimension of the conductive layer is 0.3 times the diameter of the upper surface of the contact plug (w/d=0.3). The relation of the variation in contact area to the variation in value of x/d each obtained by changing the value of h/d within the range from 0.1 to 1.0 in increments of 0.1 is shown

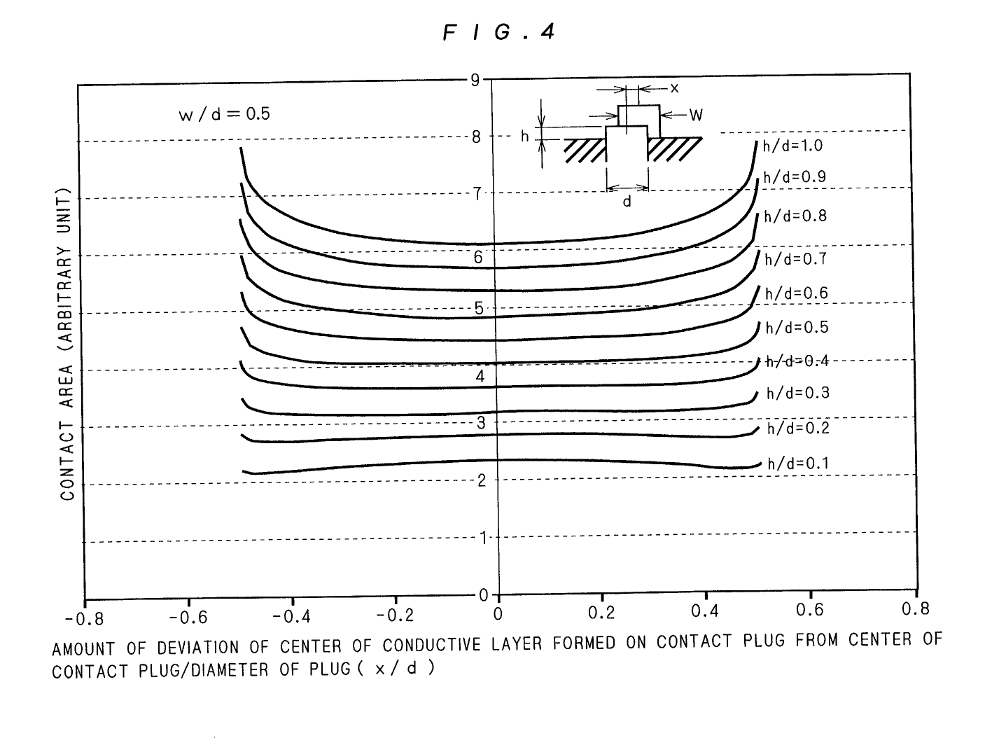

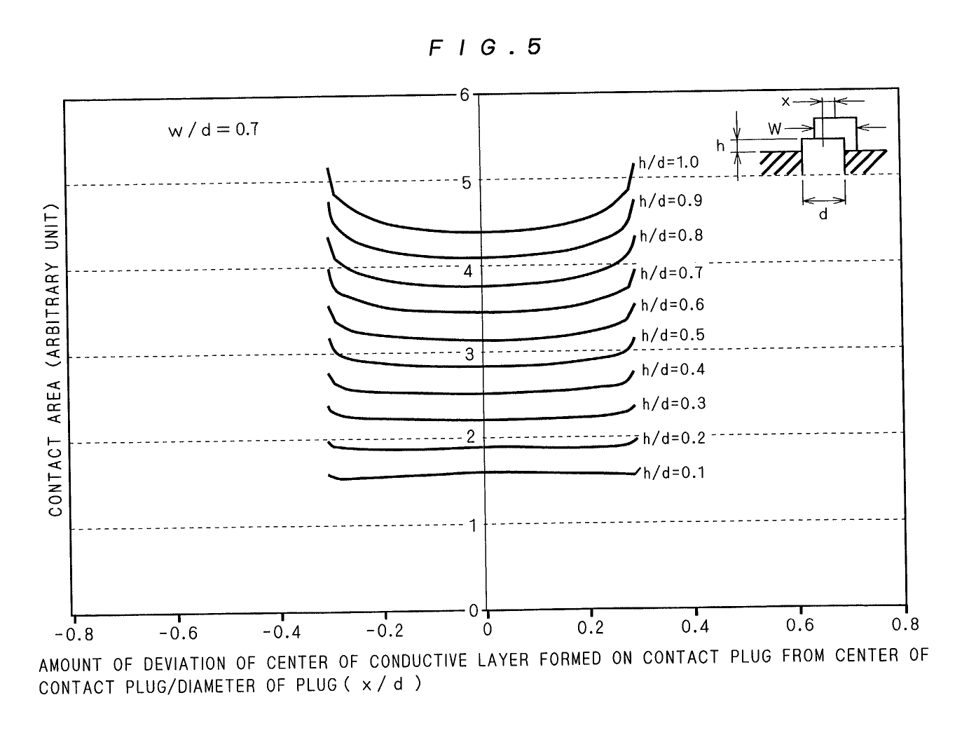

Similarly, FIG. 4 shows the example in which the short side dimension of the conductive layer is 0.5 times the diameter of the upper surface of the contact plug (w/d=0.5). Further, FIG. 5 shows the example in which the short side dimension of the conductive layer is 0.7 times the diameter of the upper surface of the contact plug (w/d=0.7).

In terms of the increase in contact area resulting from the deviation of the conductive layer, it is seen from FIGS. 3, 4 and 5 that when the value of h/d is 0.2 or more, that is, when the protrusion height h of the contact plug is 0.2 times or more the diameter of the contact plug, the increase in contact area can be realized.

<A. First Preferred Embodiment>

<A-1. Device Structure>

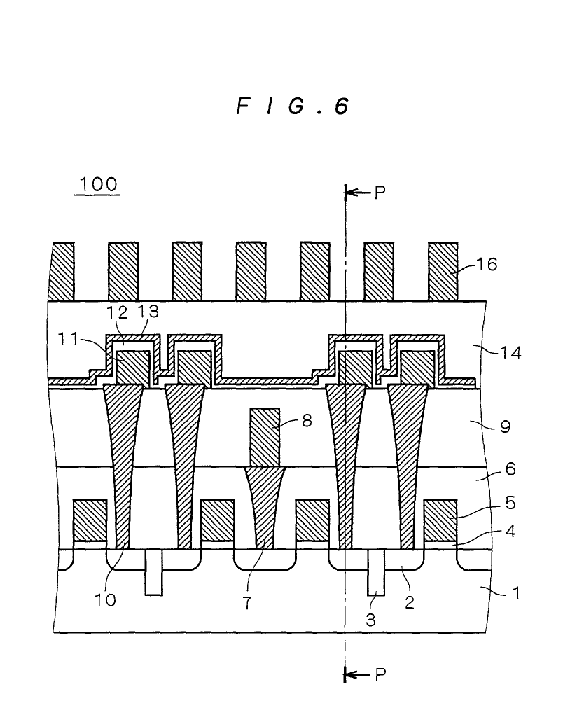

FIG. 6 is a sectional view illustrating the structure of a capacitor of a semiconductor integrated circuit 100 according to the first preferred embodiment of the present invention. As illustrated in FIG. 6, an interlayer insulating film 6 is formed on a silicon substrate 1. A plurality of contact plugs 7 (bit line contacts) each being of a cylindrical shape and penetrating through the interlayer insulating film 6 to reach the silicon substrate 1 are provided. The contact plugs 7 are made of a conductive material such as polysilicon.

On the interlayer insulating film 6, an interlayer insulating film 9 is formed for holding an interlayer insulating film 14 formed thereon. A plurality of contact plugs 10 (storage node contacts) each being of a cylindrical shape and penetrating through the interlayer insulating films 6 and 9 to reach the silicon substrate 1 are provided.

A plurality of impurity diffusion layers 2 acting as source/drain layers of MOS transistors are selectively formed in the surface of the silicon substrate 1. The main surface of the silicon substrate 1 further includes a plurality of element isolation insulating films 3 selectively formed therein for electrically isolating among the MOS transistors and defining active regions including the impurity diffusion layers 2. Further, the respective lower surfaces of the contact plugs 7 and 10 are connected to the impurity diffusion layers 2.

Each of gate electrodes 5 is formed in the interlayer insulating film 6 at a position on the silicon substrate 1 defined between adjacent impurity diffusion layers 2. A gate insulating film 4 is formed between the gate electrode 5 and the silicon substrate 1.

A plurality of bit lines 8 selectively formed in the interlayer insulating film 9 are connected to the predetermined impurity diffusion layers 2 through the contact plugs 7.

The upper surface of the contact plug 10 as an end opposite to the lower surface thereof protrudes from the main surface of the interlayer insulating film 9. On the contact plug 10, a capacitor lower electrode 11 covering the protruding part of the contact plug 10 is arranged in such a manner that the center of the contact plug 10 is located at a position deviated from a center of the contact plug 10. The protrusion height of the contact plug 10 is corresponding to the height h in the equation (2).

The capacitor lower electrode 11, a capacitor dielectric film 12 covering the capacitor lower electrode 11 and a capacitor upper electrode 13 covering the capacitor dielectric film 12 constitute a capacitor CP. As the capacitor dielectric film 12 is made of a high dielectric material such as BST (barium strontium titanate), it follows that the capacitor CP is a high-dielectric film capacitor.

A plurality of metal wires 16 having small spaces thereamong are selectively provided on the interlayer insulating film 14.

Other constituents such as wiring layer and passivation film are provided on the metal wires 16 to constitute the semiconductor integrated circuit 100. However, these constituents having little relevance to the present invention are omitted from drawings.

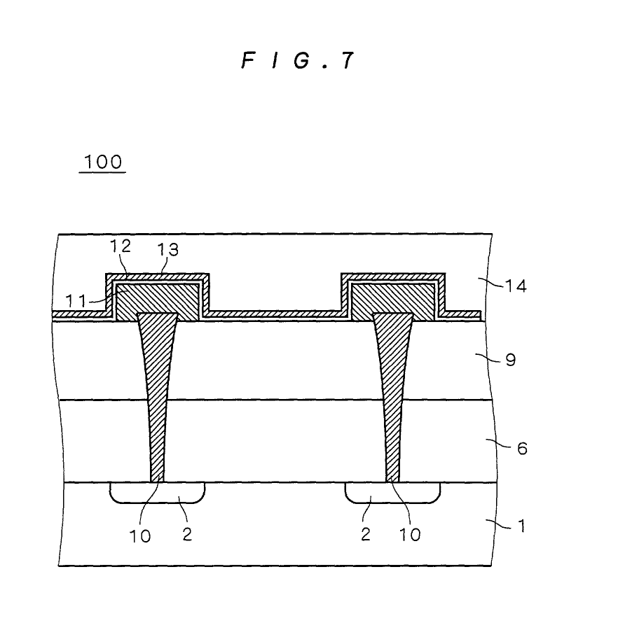

FIG. 7 is a view illustrating a section at a line P-P in FIG. 6. As illustrated in FIGS. 6 and 7, the capacitor lower electrode 11 having a rectangular-prism shape is completely covered with the capacitor dielectric film 12 and the capacitor lower electrode 13.

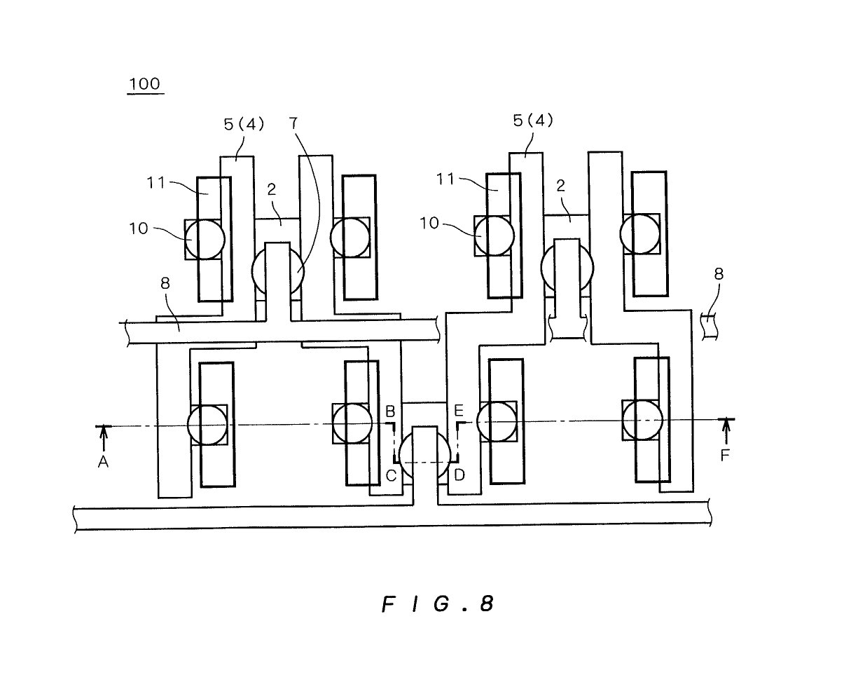

FIG. 8 is a plan view illustrating the semiconductor integrated circuit 100 looking down on from the interlayer insulating film 14. FIG. 8 includes the respective structures of the constituents underlying the capacitor lower electrode 11. The capacitor lower electrode 11 is conveniently shown only in outline so that the respective structures underlying the capacitor lower electrode 11 are explicitly described. A part of the description of the bit line 8 is omitted from FIG. 8 so that the respective underlying structures are explicitly described. A section defined at a cutting-plane line A-B-C-D-E-F in FIG. 8 is corresponding to the section illustrated in FIG. 6.

As illustrated in FIG. 8, the capacitor lower electrode 11 is arranged on each of the plurality of contact plugs 10. In each of the structure including the contact plug 10 and the capacitor lower electrode 11, the center line defined between the short sides of the capacitor lower electrode 11 deviates from the center line of the contact plug 10. Further, one of the long sides of the capacitor lower electrode 11 is positioned outside the edge of the contact plug 10.

According to the characteristics shown in FIG. 4, when the value of h/d is 0.3, for example, it is seen that the increase in contact area is realized accompanied by the deviation of the capacitor lower electrode 11 by the amount 0.4 times or more the diameter of the contact plug 10.

More particularly, in the characteristics acquired under the value of h/d which is 0.3, on the basis of the value of the contact area calculated from the value of x/d when the amount of deviation of the capacitor lower electrode 11 is zero, it is seen that the contact area starts to increase at the value of x/d which is approximately 0.4.

When the value of h/d is higher than 0.3, the value of x/d at which the contact area starts to increase is smaller than 0.4. When the value of x/d is higher than 0.5, in the characteristics acquired under the value of h/d which is 0.3, the value of x/d at which the contact area starts to increase is lower than 0.4. Conversely, when the value of w/d is lower than 0.5, in the characteristics acquired under the value of h/d which is 0.3, the value of x/d at which the contact area starts to increase is higher than 0.4. In this case, the increase in contact area occurs at the value of x/d which is approximately 0.5.

Therefore, under the condition that the protrusion height h of the contact plug is 0.2 times or more the diameter of the contact plug, the increase in contact area is ensured even when the value of x/d is 0.5 or less, that is, when the deviation of the center of the short side of the capacitor lower electrode 11 from the center of the contact plug 10 is half the diameter of the upper surface of the contact plug 10 or less.

<A-2. Function/Effect>

According to the structure described above, even in the semiconductor integrated circuit having the short side dimension of the capacitor lower electrode smaller than the diameter of the upper surface of the contact plug accompanied by the improvement in integration, the contact area between the capacitor lower electrode and the contact plug is increased. As a result, the reduction in contact resistance can be realized.

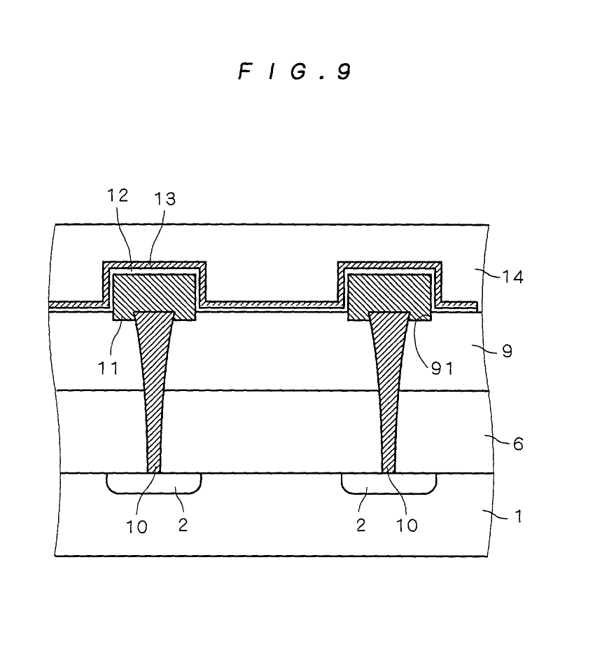

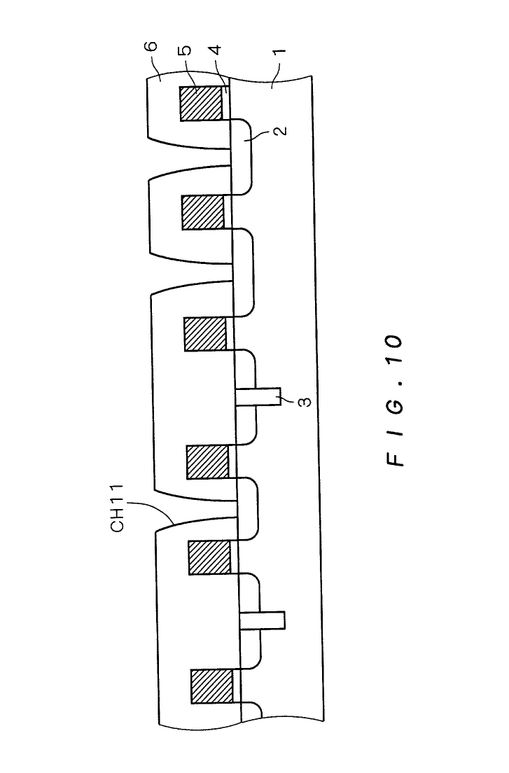

The structure illustrated in FIG. 9 is applicable for establishing connection between the side surface of the contact plug 10 and the capacitor lower electrode 11.

More particularly, in the structure illustrated in FIG. 9, a recessed portion 91 is selectively formed in the main surface of the interlayer insulating film 9. The contact plug 10 is arranged to protrude from the bottom surface of the recessed portion 91 and the capacitor lower electrode 11 is formed at the recessed portion 91. In this structure, the depth of the recessed portion 91 is corresponding to the protrusion height of the contact plug 10.

Here, it is a matter of course that the recessed portion 91 is formed to be in conformity with the shape of the capacitor lower electrode 11.

<A-3. Manufacturing Method>

The method of manufacturing the semiconductor integrated circuit 100 will be described in reference to FIGS. 10 to 17 which illustrate manufacturing steps in sequential order. FIGS. 10 to 17 illustrate the steps of manufacturing the structures in the vicinity of the capacitor as well as the steps of manufacturing the capacitor.

In the steps illustrated in FIG. 10, according to the manufacturing method conventionally employed, the element isolation insulating films 3 are formed in the main surface of the semiconductor substrate 1 for defining the active regions. The impurity diffusion layers 2 acting as the source/drain layers of the MOS transistors are selectively formed in the active regions. A plurality of gate electrodes 5 are selectively formed at the positions on the silicon substrate 1 defined between adjacent impurity diffusion layers 2. Each of the plurality of gate electrodes 5 holds the gate insulating film 4 formed between the same and the silicon substrate 1. The interlayer insulating film 6 made of a material such as TEOS (tetraethyl orthosilicate) is formed by using a low-pressure CVD (chemical vapor deposition) method, for example, to cover the main surface of the semiconductor substrate 1 and the gate electrodes 5.

A plurality of contact holes CH1 penetrating through the interlayer insulating film 6 are provided by means of photolithography and dry etching to reach the respective surfaces of the predetermined impurity diffusion layers 2. Here, due to etching characteristics, for example, each of the contact holes CH1 includes an upper opening having an area larger than the area of the lower opening thereof.

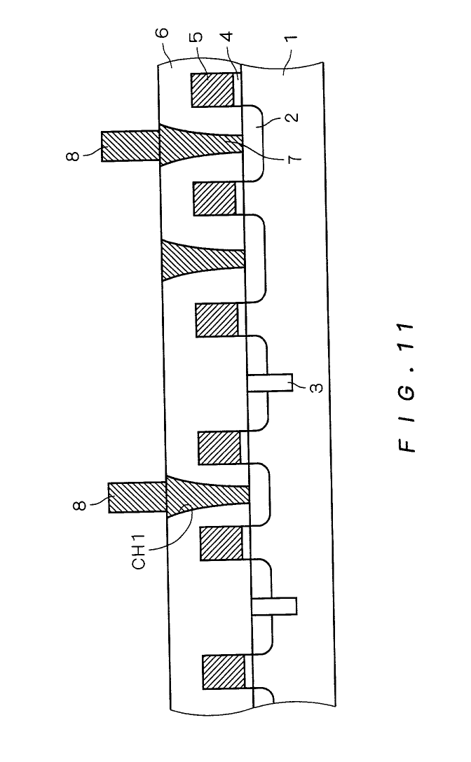

Next, in the steps illustrated in FIG. 11, a polysilicon layer is formed all over the main surface of the interlayer insulating film 6 by using the method such as CVD, to thereby fill the contact holes CH1 with the polysilicon layer. Thereafter the polysilicon layer is planarized by using the technique such as CMP (chemical mechanical polishing) so that the polysilicon layer on the interlayer insulating film 6 is removed. The plurality of contact plugs 7 are thereby formed by filling the plurality of contact holes CH1 with the conductive layer.

Then, layers consisting of Ti (titanium), TiN (titanium nitride) and W (tungsten) are sequentially formed all over the main surface of the interlayer insulating film 6 by using the method such as sputtering. These layers are patterned by means of photolithography and dry etching to form the bit lines 8. Here, connection is established between each of the bit lines 8 and the upper surface of the predetermined contact plug 7. Some of the contact holes 7 have no connection to the bit line 8.

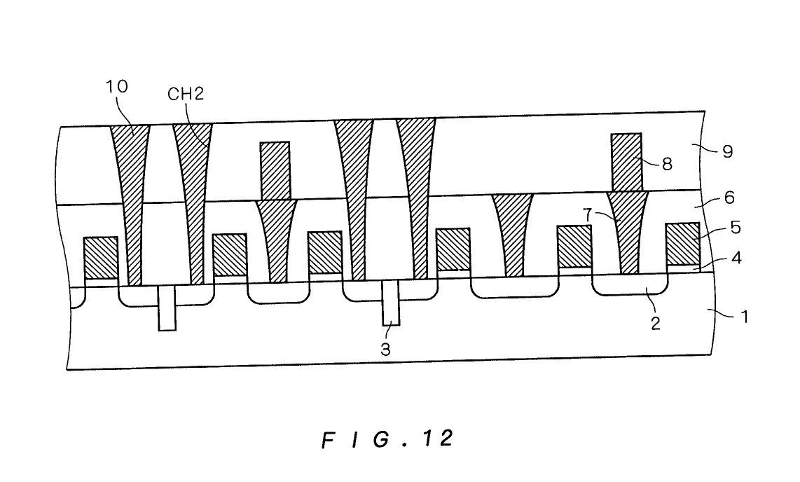

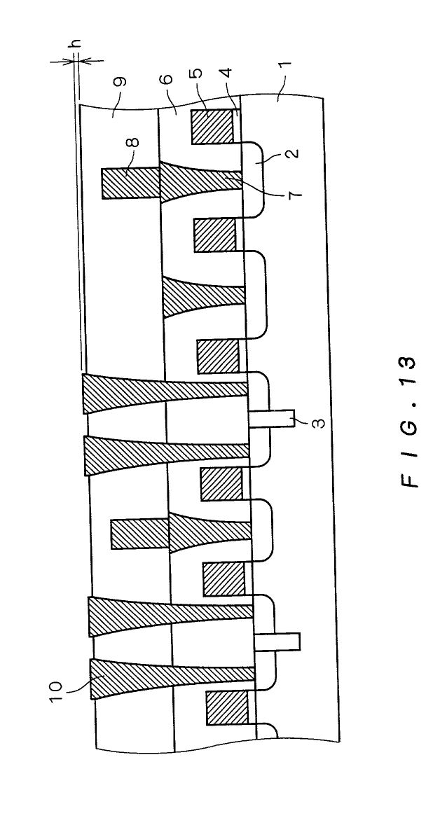

Next, in the steps illustrated in FIG. 12, the interlayer insulating film 9 made of a material such as silicon oxide is formed all over the main surface of the interlayer insulating film 6 by using the method such as plasma CVD to completely cover the bit line 8.

A plurality of contact holes CH2 penetrating through the interlayer insulating films 6 and 9 are formed by means of photolithography and dry etching to reach the respective surfaces of the predetermined impurity diffusion layers 2. Here, due to etching characteristics, for example, each of the contact holes CH2 includes an upper opening having an area larger than the area of the lower opening thereof.

Thereafter, following the steps same as the steps of forming the contact plugs 7, the contact holes CH2 are filled with the conductive layer to form the contact plugs 10. Here, the conductive material used for filling the contact holes CH2 may not be required to be the same as the conductive material used for filling the contact holes CH1 to form the contact plugs 7.

Next, in the steps illustrated in FIG. 13, the surface of the interlayer insulating film 9 is etched back by a predetermined depth by dry etching, for example. The upper portion of each of the contact plugs 10 then protrudes. The depth of etching mentioned here is corresponding to the height h in the equation (2).

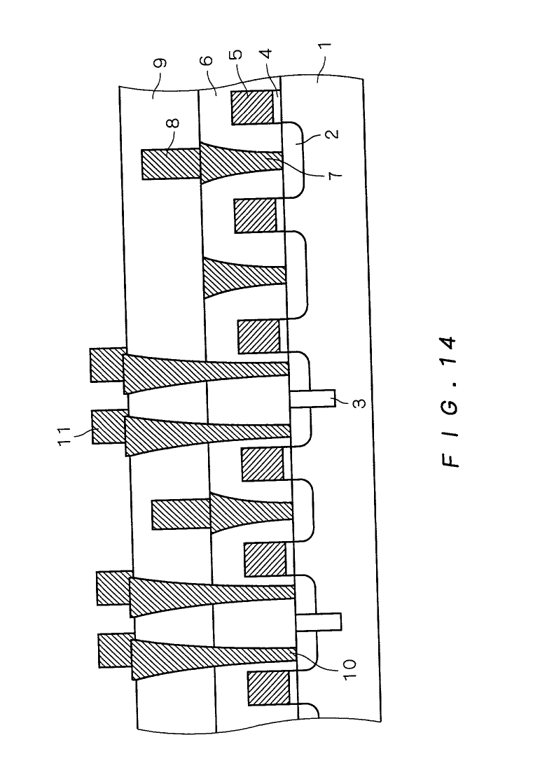

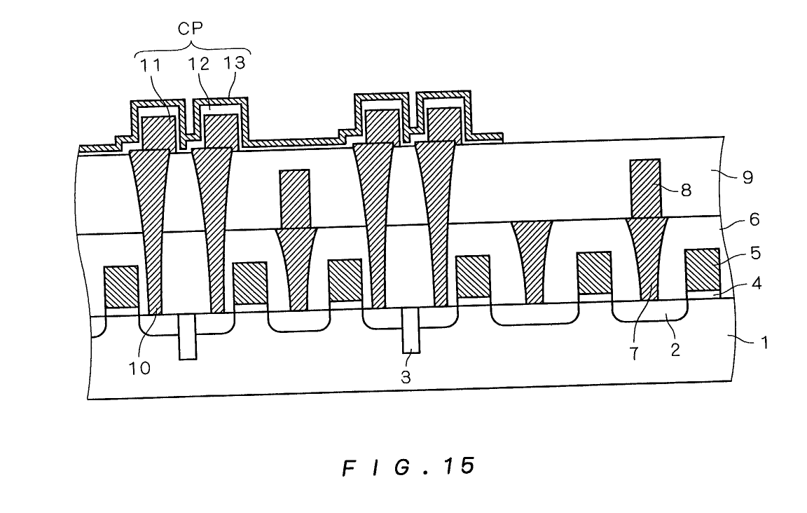

Thereafter, in the steps illustrated in FIG. 14, a conductive layer made of a material such as Ru(ruthenium) is formed all over the main surface of the interlayer insulating film 9 by using the method such as sputtering. This conductive layer is patterned by means of photolithography and dry etching to form the capacitor lower electrode 11. The material for the capacitor lower electrode 11 is not limited to Ru. Alternative material such as other platinum-group elements (Pt, Rh, Pd, Os, Ir) or refractory metal, or alternatively, nitride or oxy-nitride formed therefrom is applicable. Further alternatively, a composite of these materials is applicable as well.

As shown in FIG. 8, the capacitor lower electrode 11 of a rectangular-prism shape has the short side dimension smaller than the diameter of the upper surface of the contact plug 10. Further, the capacitor lower electrode 11 is arranged in such a manner that the center line defined between the short sides of the capacitor lower electrode 11 deviates from the center line of the contact plug 10. In the structure illustrated in FIG. 14, one of the long sides of the capacitor lower electrode 11 is positioned outside the edge of the contact plug 10.

According to the structure described above, the contact area between the capacitor lower electrode 11 and the contact plug 10 is increased to thereby realize the reduction in contact resistance.

Then, in the steps illustrated in FIG. 15, the capacitor dielectric film 12 made of a high dielectric material such as BST is formed all over the main surface of the interlayer insulating film 9 by using the method such as sputtering to cover the capacitor lower electrode 11. Over the capacitor dielectric film 12, the capacitor upper electrode 13 made of platinum-group elements such as Pt, Ru or refractory metals such as W, Ti is formed by sputtering method, for example. Here, as the material for the capacitor upper electrode 13, nitride or oxy-nitride formed therefrom, or alternatively, a composite of these materials is applicable as well. The capacitor dielectric film 12 and the capacitor upper electrode 13 formed all over the main surface of the interlayer insulating film 9 are patterned by means of photolithography and dry etching to constitute the capacitor CP as illustrated in FIG. 15.

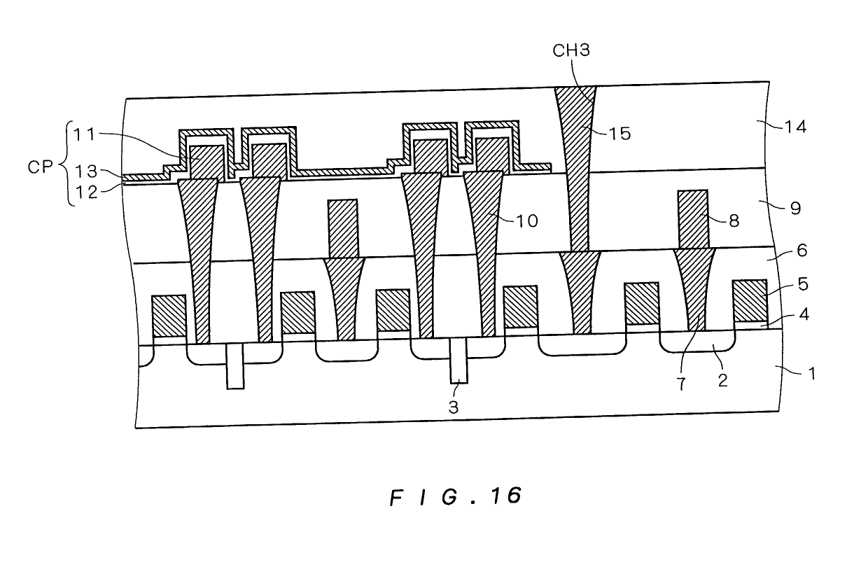

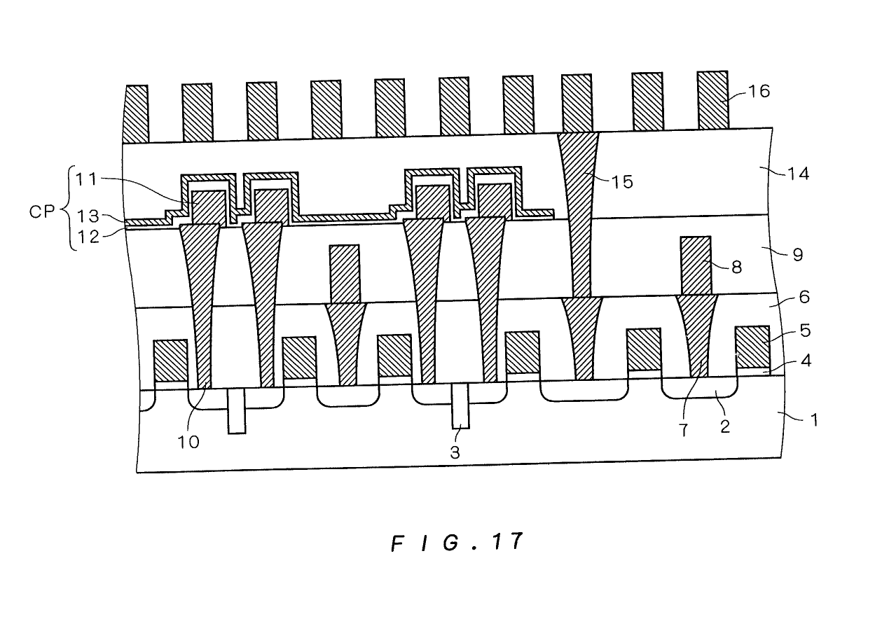

Next, in the steps illustrated in FIG. 16, the interlayer insulating film 14 made of silicon oxide and the like is formed all over the main surface of the interlayer insulating film 9 by using the method such as plasma CVD to completely cover the capacitor CP.

Thereafter, a plurality of contact holes CH3 penetrating through the interlayer insulating films 14 and 9 are provided by means of photolithography and dry etching to reach the respective upper surfaces of the contact plugs 7 having no connection to the bit line 8. Here, due to etching characteristics, for example, each of the contact holes CH3 includes an upper opening having an area larger than the area of the lower opening thereof.

Then, following the steps same as the steps of forming the contact plugs 7, the contact holes CH3 are filled with the conductive layer to form contact plugs 15. The contact plug 15 and the contact plug 7 having connection to the contact plug 15 constitute a stacked via contact. Unlike the other contact plugs 7 each connected to the bit line 8, the contact plug 7 connected to the contact plug 15 has no connection to the bit line 8. However, as such contact plug 7 is formed by following the steps same as the steps of forming the other contact plugs 7, it may be called as bit line contact.

The conductive material used for filling the contact holes CH3 may not be required to be the same as the conductive material used for filling the contact holes CH1 and CH2 to form the contact plugs 7 and 10, respectively.

Next, in the steps illustrated in FIG. 17, layers consisting of Ti, TiN and Al (aluminum) are sequentially formed all over the main surface of the interlayer insulating film 14 by using the method such as sputtering. These layers are patterned by means of photolithography and dry etching to form the plurality of metal wires 16. Here, the connection is established between some of the plurality of metal wires 16 and the upper surface of the contact plug 15.

The method of forming the metal wires 16 and the material for the same are not limited to those described above. Alternatively, the metal wires 16 may be provided through damascene process for processing Cu (copper) that is obtained by plating.

In the subsequent steps, the wiring layer and passivation film are formed on the metal wires 16. As these constituents are formed by the known technique conventionally used, the description thereof is omitted here.

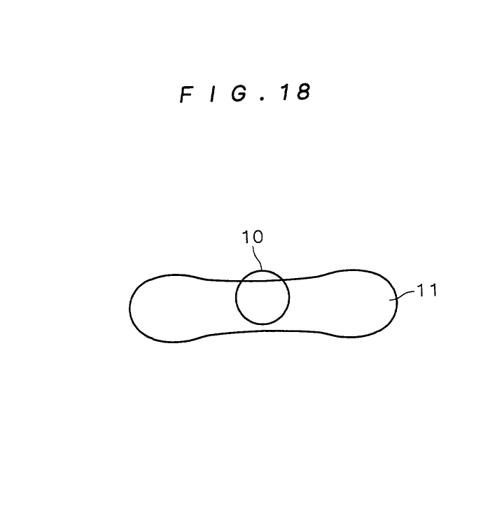

The foregoing description has been given on the basis of the conditions that the capacitor lower electrode 11 is a long thin shape in a plan view having the short side of the dimension smaller than the diameter of the contact plug 10 as illustrated in FIG. 8. Alternatively, the center part of the capacitor lower electrode 11 in a longitudinal direction may be constricted so that the capacitor lower electrode 11 includes the constricted part in the center thereof having the short side dimension smaller than that of a part other than the constricted part as illustrated in FIG. 18, for example. The present invention is further applicable to the structure including the capacitor lower electrode 11 of this configuration. In such structure, the capacitor lower electrode 11 may be arranged in such a manner that the constricted part thereof is positioned on the contact plug 10.

The foregoing description has been given on the basis of the further conditions that the contact plug 10 of a cylindrical shape has a circular shape on the upper and lower surfaces thereof. However, the shape of the contact plug 10 is not limited to the cylinder. The section of the contact plug 10 may be elliptical, or alternatively, of an oval shape including ends each being of a semicircle having a curvature and including center parts linearly extending such as a track in the athletics. Even when the contact plug 10 has a section of either one of these shapes, the same effects can be achieved by arranging the capacitor lower electrode 11 at a deviated position.

When the contact plug 10 is not of a cylindrical shape, according to the shapes of the upper and lower surfaces thereof, the cross-sectional dimensions of lines extending through the respective centers of the upper and lower surfaces of the contact plug 10 in a predetermined direction can be applicable instead of the diameter of the same. Here, the amount of deviation of the capacitor lower electrode 11 is determined by using these cross-sectional dimensions.

<B. Second Preferred Embodiment>

<B-1. Device Structure>

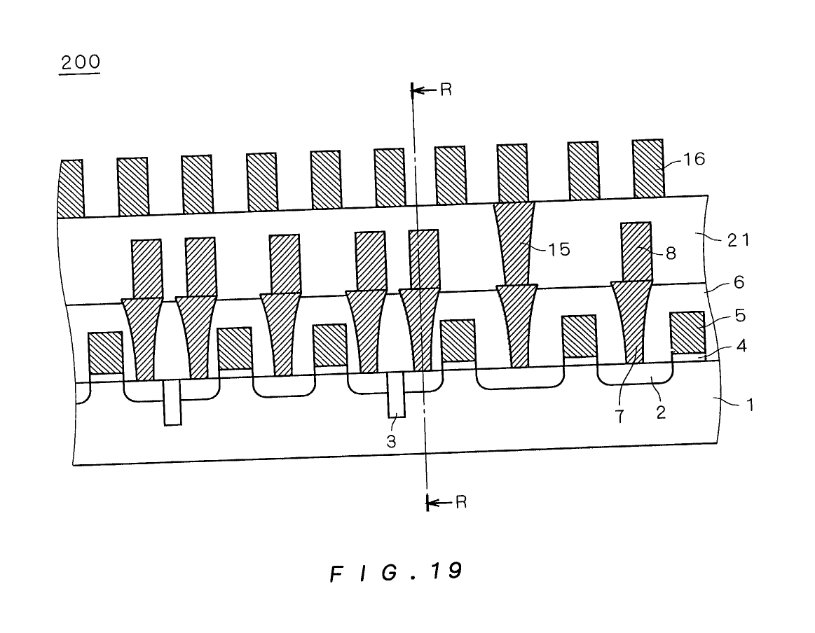

FIG. 19 is a sectional view illustrating the structure of a semiconductor integrated circuit 200 according to the second preferred embodiment of the present invention. As illustrated in FIG. 19, an interlaying insulating film 6 is formed on a silicon substrate 1. A plurality of contact plugs 7 penetrating through the interlayer insulating film 6 to reach the silicon substrate 1 are provided. The contact plugs 7 are made of a conductive material such as polysilicon.

An interlayer insulating film 21 is formed on the interlayer insulating film 6. A contact plug 15 of a cylindrical shape penetrating through the interlayer insulating film 21 to reach the upper surface of some of the contact plugs 7 is provided.

The structure including impurity diffusion layers 2 and element isolation insulating films 3 formed in the surface of the silicon substrate 1, and further including gate electrodes 5 formed in the interlayer insulating film 6 is also the part of the structure of the semiconductor integrated circuit 100 described in reference to FIG. 6. Therefore, the description thereof is not repeatedly given here. Further, the respective lower surfaces of the contact plugs 7 are connected to the impurity diffusion layers 2.

A plurality of bit lines 8 selectively formed in the interlayer insulating film 21 are connected to the predetermined impurity diffusion layers 2 through the contact plugs 7.

The contact plug 15 and the contact plug 7 having connection to the contact plug 15 constitute a stacked via contact. The connection is further established between this stacked via contact and one of the impurity diffusion layers 2.

The upper surface of the contact plug 7 as an end opposite to the lower surface thereof protrudes from the main surface of the interlayer insulating film 6. The protrusion height of the contact plug 7 is corresponding to the height h in the equation (2). The bit line 8 is arranged on the upper surface of the contact plug 7 in such a manner that the center of the bit line 8 is located at a position deviated from the center of the contact plug 7.

The amount of deviation of the bit line 8 is also determined by the characteristics shown in FIG. 4. When the value of h/d is 0.3, for example, it is seen that the increase in contact area is realized with the deviation of the bit line 8 by the amount 0.4 times or more the diameter of the contact plug 7.

A plurality of metal wires 16 having small spaces thereamong are selectively provided on the interlayer insulating film 21. Here, the connection is established between some of the metal wires 16 and the upper surface of the contact plug 15.

Making the assumption that the short side dimension of each of the metal wires 16 is smaller than the diameter of the upper surface of the contact plug 15, similar to the bit line 8, the metal wire 16 is arranged on the upper surface of the contact plug 15 in such a manner that the center of the metal wire 16 is located at a position deviated from the center of the contact plug 15. It is a matter of course that the increase in contact area is realized as well by employing this arrangement.

Other constituents such as wiring layer and passivation film are provided on the metal wires 16 to constitute the semiconductor integrated circuit 200. However, these constituents having little relevance to the present invention are omitted from drawings.

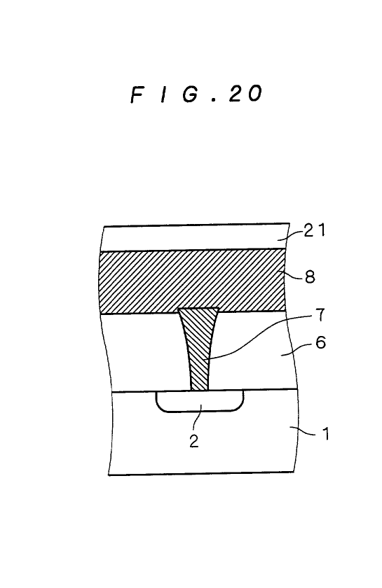

FIG. 20 is a view illustrating a section at a line R-R in FIG. 19. As illustrated in FIG. 20, the bit line 8 has connection in a longitudinal direction to the side surface of the protruding part of the contact plug 7.

<B-2. Function/Effect>

According to the structure described above, even in the semiconductor integrated circuit including various types of wiring layers such as the bit line having a short side dimension smaller than the diameter of the upper surface of the contact plug accompanied by the improvement in integration, the contact area between the wiring layer and the contact plug is increased. As a result, the reduction in contact resistance can be realized.

<B-3. Manufacturing Method>

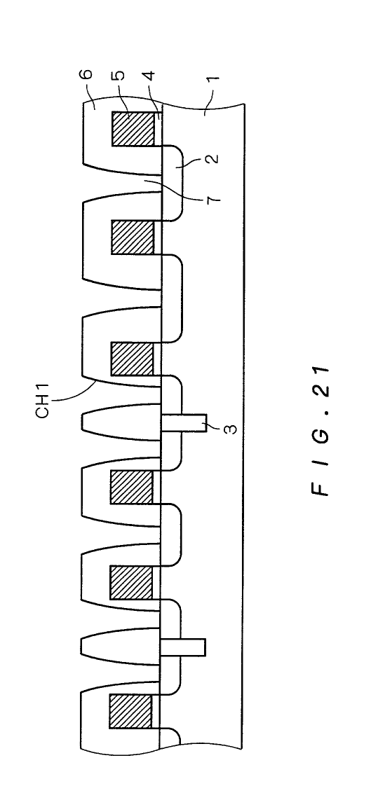

The method of manufacturing the semiconductor integrated circuit 200 will be described in reference to FIGS. 21 to 25 which illustrate manufacturing steps in sequential order.

First, in the steps illustrated in FIG. 21, the interlayer insulating film 6 made of a material such as TEOS is formed by using a low-pressure CVD method, for example, to cover the main surface of the semiconductor substrate 1. The methods of forming the constituents in the main surface of the semiconductor substrate 1 and other constituents such as a gate insulating film 4 and the gate electrode 5 are the same as the methods already described in reference to FIG. 10. Due to this, the constituents same as those in the first preferred embodiment are designated by the same reference numerals and the detailed description thereof is omitted here.

A plurality of contact holes CH1 penetrating through the interlayer insulating film 6 are provided by means of photolithography and dry etching to reach the surface of the predetermined impurity diffusion layer 2.

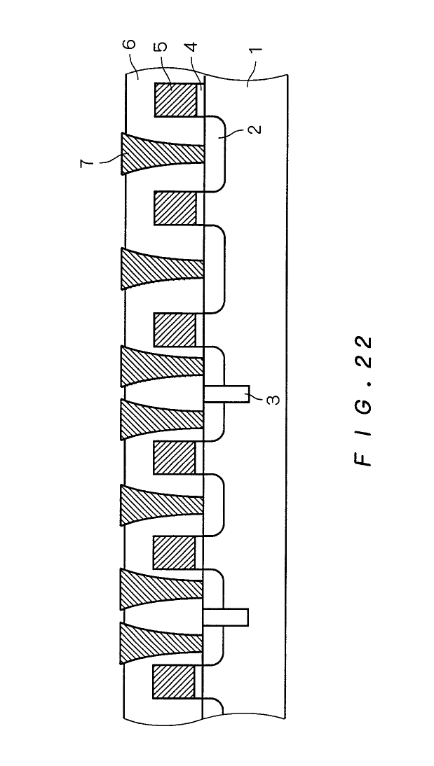

Next, in the steps illustrated in FIG. 22, a polysilicon layer is formed all over the main surface of the interlayer insulating film 6 by using the method such as CVD to fill the contact holes CH1 with the polysilicon layer. Thereafter the polysilicon layer is planarized by using the technique such as CMP so that the polysilicon layer on the interlayer insulating film 6 is removed. The plurality of contact plugs 7 are thereby formed by filling the contact holes CH1 with the conductive layer. The method used for the planarization of the polysilicon layer is not limited to CMP. The alternative method such as etch back is applicable.

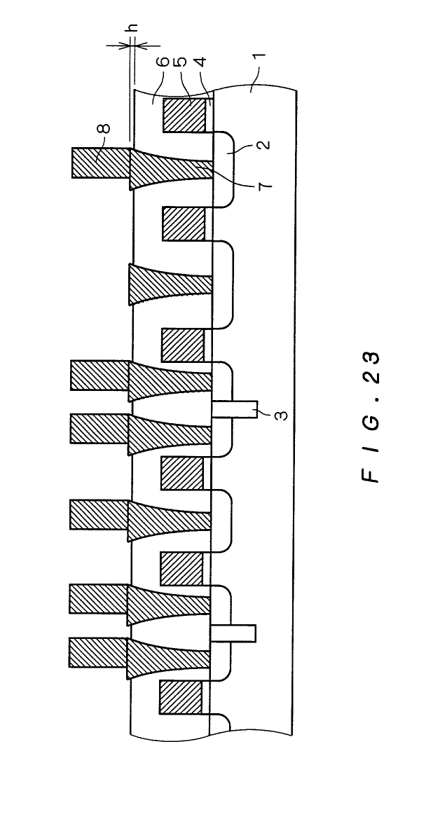

Then, in the steps illustrated in FIG. 23, the surface of the interlayer insulating film 6 is etched back by a predetermined depth by etching using HF diluent, for example. The upper portion of the contact plug 7 protrudes accordingly. The depth of etching mentioned here is corresponding to the height h in the equation (2).

Next, layers consisting of Ti, TiN and W are sequentially formed all over the main surface of the interlayer insulating film 6 by using the method such as sputtering. These layers are patterned by means of photolithography and dry etching to form the bit lines 8. Here, the connection is established between each of the bit lines 8 and the upper surface of the predetermined contact plug 7. Further, the bit line 8 is arranged in such a manner that the center line defined between the short sides thereof deviates from the contact plug 7. As illustrated in FIG. 23, the edge of one of the long sides of the bit line 8 marginally coincides with the edge of the contact plug 7.

According to the structure described above, the contact area between the bit line 8 and the contact plug 7 is increased to thereby realize reduction in contact resistance.

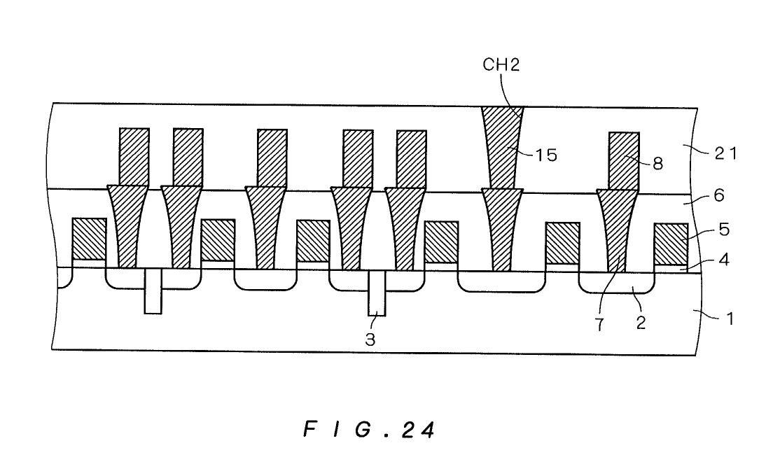

Thereafter, in the steps illustrated in FIG. 24, the interlayer insulating film 21 made of a material such as silicon oxide is formed all over the main surface of the interlayer insulating film 6 by using the method such as plasma CVD to completely cover the bit line 8.

Next, a contact hole CH2 penetrating through the interlayer insulating film 21 is formed by means of photolithography and dry etching to reach the upper surface of the predetermined contact plug 7. Here, due to etching characteristics, for example, the contact hole CH2 includes an upper opening having an area larger than the area of the lower opening thereof.

Thereafter, following the steps same as the steps of forming the contact plugs 7, the contact hole CH1 is filled with the conductive layer to form a contact plug 15. Here, the conductive material used for filling the contact hole CH2 may not be required to be the as the conductive material used for filling the contact holes CH1 to form the contact plugs 7.

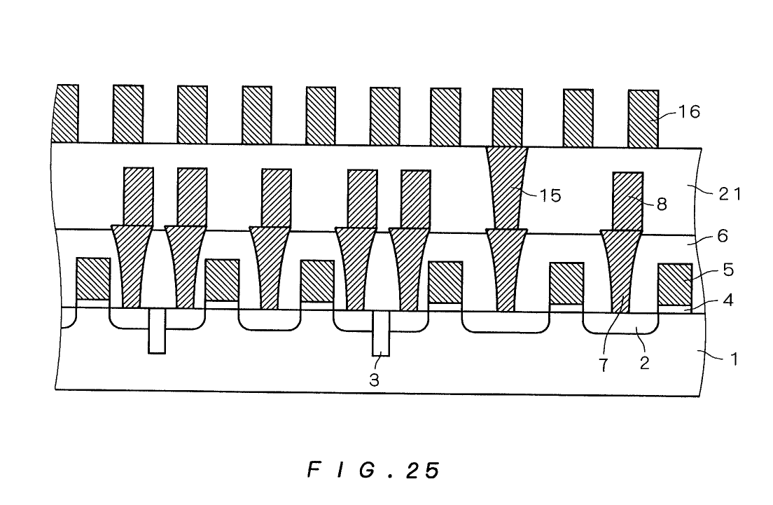

After this, in the steps illustrated in FIG. 25, layers consisting of Ti, TiN and Al are sequentially formed all over the main surface of the interlayer insulating film 21 by using the method such as sputtering. These layers are patterned by means of photolithography and dry etching to form the plurality of metal wires 16. Here, the connection is established between some of the plurality of metal wires 16 and the upper surface of the contact plug 15.

The method of forming the metal wires 16 and the material therefor are not limited to those described above. Alternatively, the metal wires 16 may be provided through damascene process for processing Cu (copper) that is obtained by plating.

In the subsequent steps, the wiring layer and passivation film are formed on the metal wires 16. As these constituents are formed by the known technique conventionally used, the description thereof is omitted here.

The foregoing description has been given on the basis of the condition that the contact plug 7 of a cylindrical shape has a circular shape on the upper and lower surfaces thereof. However, the shape of the contact plug 7 is not limited to the cylindrical shape. The section of the contact plug 7 may be elliptical, or alternatively, of an oval shape including ends each being of a semicircle having a curvature and including center parts linearly extending such as a track in the athletics. Even when the contact plug 7 has a section of either one of these shapes, the same effects can be achieved by arranging the bit line 8 at a deviated position.

When the contact plug 7 is not of a cylindrical shape, according to the shapes of the upper and lower surfaces thereof, the cross-sectional dimensions of lines extending through the respective centers of the upper and lower surfaces of the contact plug 7 in a predetermined direction can be applicable instead of the diameter of the same. Here, the amount of deviation of the bit line 8 is determined by using these cross-sectional dimensions.

<B-4. Modification of Manufacturing Method>

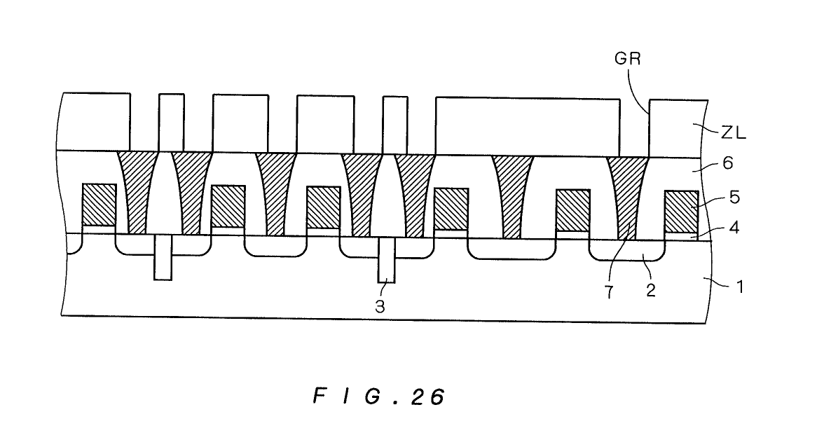

The bit line 8 may be formed through damascene process. The method of forming the bit line 8 through damascene will be described with reference to FIGS. 26 to 28.

After formation of the plurality of contact plugs 7 penetrating through the interlayer insulating film 6 through the steps illustrated in FIGS. 21 and 22, an insulating film ZL is formed all over the main surface of the interlayer insulating film 6 in the steps illustrated in FIG. 26. Next, a plurality of trenches GR penetrating through the insulating film ZL to reach the upper surfaces of the predetermined contact plugs 7 are formed by means of photolithography and dry etching to be in conformity with the pattern of the bit line 8.

Here, it is required that the trenches GR are arranged in such a manner that each center line thereof is located at a position deviated from the center line of each of the contact plugs 7. Further, resulting from over etching performed during formation of the trenches GR, the side surface of each contact plug 7 as well as the upper surface thereof is exposed to the bottom surface of each trench GR. The depth of over etching mentioned here is corresponding to the height h in the equation (2).

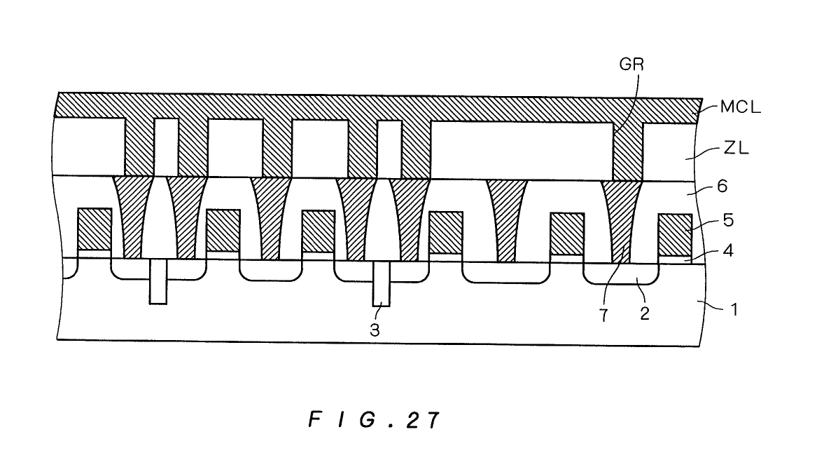

Next, in the steps illustrated in FIG. 27, layers consisting of Ti and TiN are sequentially formed all over the main surface of the insulating film ZL by using the method such as sputtering. On these layers, a layer consisting of W is further formed by using the CVD method, to constitute a multilayered conductive layer MCL. The trenches GR are then filled with the multilayered conductive layer MCL.

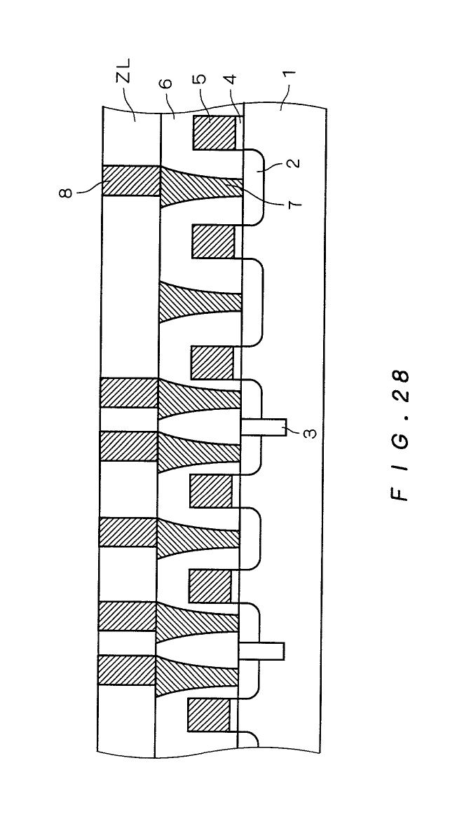

Thereafter, in the steps illustrated in FIG. 28, the multilayered conductive layer MCL is planarized by using the technique such as CMP so that the multilayered conductive layer MCL on the insulating film ZL is removed. The plurality of bit lines 8 are thereby formed by filling the plurality of trenches GR with the multilayered conductive layer. After this, the insulating ZL is removed. Here, the method of planarizing the multilayered conductive layer MCL is not limited to CMP. The alternative method such as etch back is applicable.

Since the bit line 8 is formed through damascene process, the height of the protrusion of the contact plug 7 differs from that of the contact plug 7 which is defined by the bit line 8 formed through the steps illustrated in FIG. 23. However, the reduction in contact resistance can be realized to the same extent.

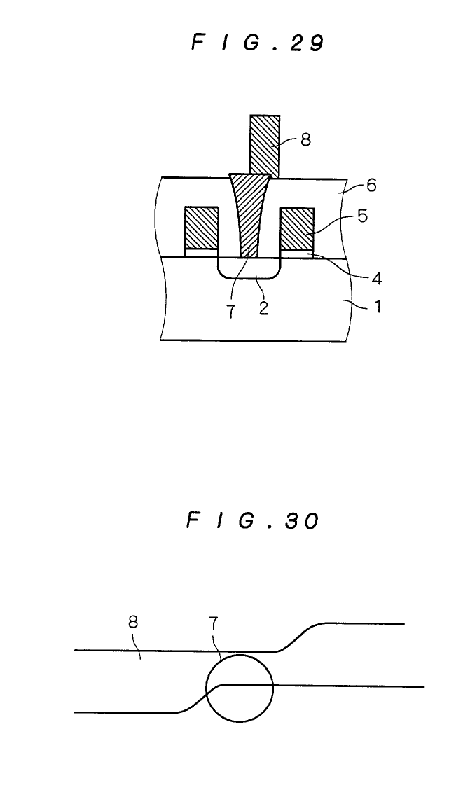

In the semiconductor integrated circuit 200 described above, the edge of one of the long sides of the bit line 8 marginally coincide with the edge of the contact plug 7 as illustrated in FIG. 19. It is a matter of course, on the other hand, that the bit line 8 may be provided in such a manner that the edge of one of the long sides thereof is positioned outside the edge of the contact plug 7. One example of this structure is given in FIG. 29.

FIG. 29 illustrates only one of the contact plugs 7 and one of the bit lines 8 connected thereto. As illustrated in FIG. 29, the edge of one of the long sides of the bit line 8 is positioned outside the edge of the contact plug 7.

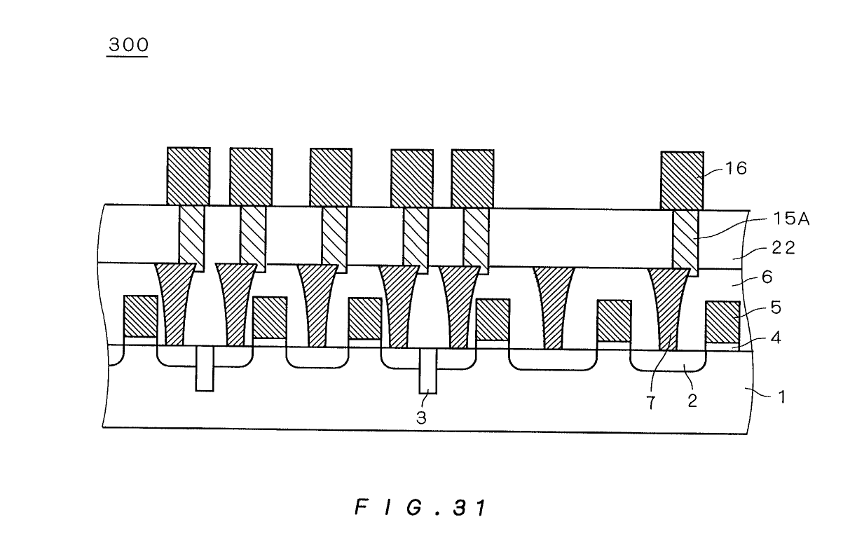

In the semiconductor integrated circuit 200 described above, the dimension of the short side of the bit line 8 is smaller than the diameter of the contact plug 7. There is no change in short side dimension of the bit line 8. That is, the short side dimension of the bit line 8 illustrated in FIG. 8 is described as the constant dimension thereof. On the other hand, the present invention is applicable as well to the structure including the bit line 8 having different short side dimensions as illustrated in FIG. 30, for example.

The applicability of the present invention is not limited to the bit line. It is further applicable to the structure including the wiring layer having connection to the contact plug.

<C. Third Preferred Embodiment>

<C-1. Device Structure>

FIG. 31 is a sectional view illustrating the structure of a semiconductor integrated circuit 300 according to the third preferred embodiment of the present invention. As illustrated in FIG. 31, an interlayer insulating film 6 is formed on a silicon substrate 1. A plurality of contact plugs 7 penetrating through the interlayer insulating film 6 to reach the silicon substrate 1 are provided. The contact plugs 7 are made of a conductive material such as polysilicon.

An interlayer insulating film 22 is formed on the interlayer insulating film 6. Contact plugs 15A each being of a cylindrical shape and penetrating through the interlayer insulating film 22 to reach the respective upper surfaces of the contact plugs 7 are provided.

The structure including impurity diffusion layers 2 and element isolation insulating films 3 in the surface of the silicon substrate 1, and further including gate electrodes 5 is also the part of the structure of the semiconductor integrated circuit 100 described in reference to FIG. 6. Therefore, the description thereof is not repeatedly given here. Further, the respective lower surfaces of the contact plugs 7 are connected to the impurity diffusion layers 2.

The contact plug 15A and the contact plug 7 having connection to the contact plug 15A constitute a stacked via contact.

The contact plug 15A is arranged in such a manner that the center of the contact plug 15A is located at a position deviated from the center of the contact plug 7 and that a part of the edge of the contact plug 15A is positioned outside the edge of the contact plug 7 entering into the surface of the interlayer insulating film 6 to reach the side surface of the contact plug 7.

The amount of deviation of the contact plug 15A cannot be exactly determined from the characteristics shown in FIG. 4. However, the increase in contact area is realized here exhibiting characteristics similar to those shown in FIG. 4. The contact area is therefore increased with the deviation of the contact plug 15A by the amount 0.4 times or more the diameter of the contact plug 7.

A plurality of metal wires 16 having small spaces thereamong are selectively formed on the interlayer insulating film 22. Each of the plurality of metal wires 16 is connected to the respective upper surfaces of the contact plugs 15A.

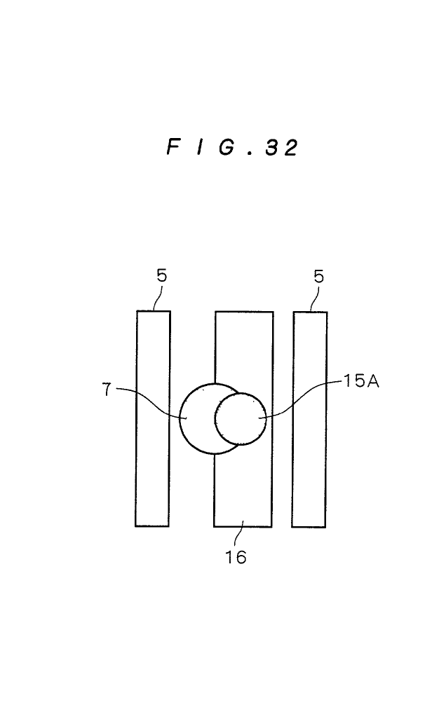

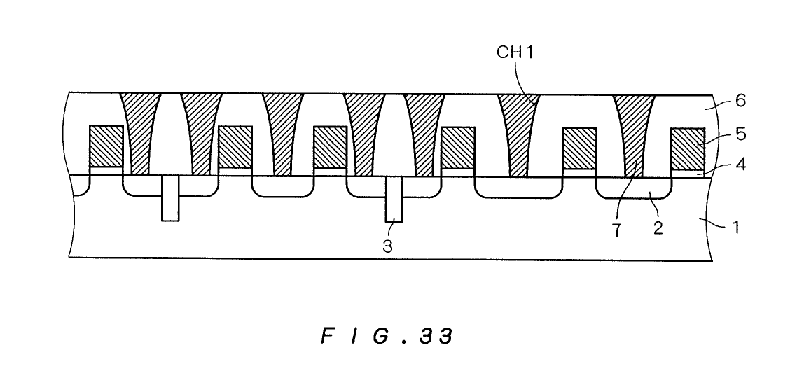

FIG. 32 is a plan view illustrating how the contact plug 15A is overlaid on the contact plug 7. In FIG. 32, the structure of one stacked via contact is illustrated looking down on from the interlayer insulating film 22 to show that the part of the edge of the contact plug 15A is positioned outside the edge of the contact plug 7. FIG. 32 further includes the metal wire 16 and the gate electrode 5 for convenience of description.

Other constituents such as wiring layer and passivation film are provided on the metal wires 16 to constitute the semiconductor integrated circuit 300. However, these constituents having little relevance to the present invention are omitted from drawings.

<C-2. Function/Effect>

According to the structure described above, even in the semiconductor integrated circuit including the plurality of contact plugs for forming stacked via contacts and more particularly, including upper and lower contact plugs arranged in a vertical direction in which the diameter of the lower surface of the upper contact plug is smaller than the diameter of the upper surface of the lower contact plug accompanied by the improvement in integration, the contact area between the upper and lower contact plugs is increased. As a result, the reduction in contact resistance can be realized.

<C-3. Manufacturing Method>

The method of manufacturing the semiconductor integrated circuit 300 will be described in reference to FIGS. 33 to 36 which illustrate manufacturing steps in sequential order.

First, in the steps illustrated in FIG. 33, the interlayer insulating film 6 made of a material such as TEOS is formed by using a low-pressure CVD method, for example, to cover the main surface of the semiconductor substrate 1. The methods of forming the constituents in the main surface of the semiconductor substrate 1 and other constituents such as a gate insulating film 4 and the gate electrode 5 are the same as the methods already described in reference to FIG. 10. Due to this, the constituents same as those in the first preferred embodiment are designated by the same reference numerals and the detailed description thereof is omitted here.

A plurality of contact holes CH1 penetrating through the interlayer insulating film 6 are provided by means of photolithography and dry etching. After this, a polysilicon layer is formed all over the main surface of the interlayer insulating film 6 by using the method such as CVD to fill the contact holes CH1 with the polysilicon layer. Thereafter the polysilicon layer is planarized by using the technique such as CMP so that the polysilicon layer on the interlayer insulating film 6 is removed. The plurality of contact plugs 7 are thereby formed by filling the contact holes CH1 with the conductive layer.

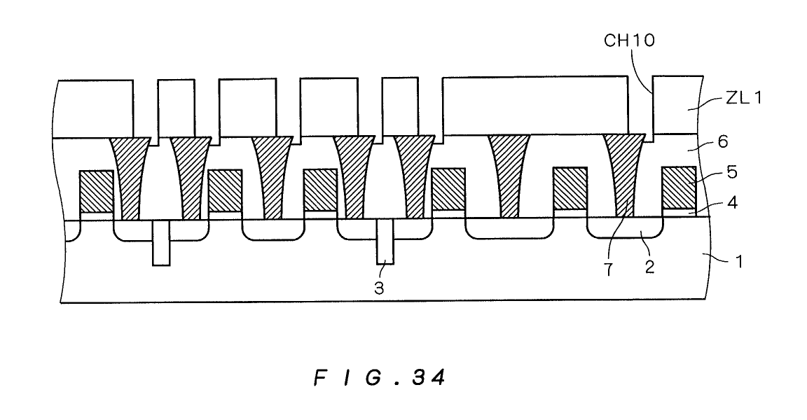

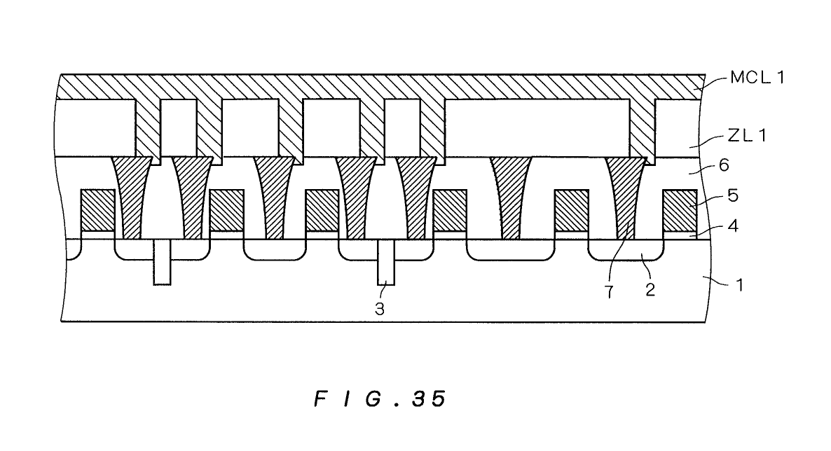

Thereafter, in the steps illustrated in FIG. 34, an insulating film ZL1 is formed all over the main surface of the interlayer insulating film 6. Next, a plurality of contact holes CH10 penetrating through the insulating film ZL1 to reach the respective upper surfaces of the predetermined contact plugs 7 are provided by means of photolithography and dry etching.

Here, it is required that the contact holes CH10 are arranged in such a manner that the center line of each of the contact holes CH10 is located at a position deviated from the center line of each of the contact plugs 7. Further, resulting from over etching performed during formation of the contact holes CH10, the side surface of each contact plug 7 as well as the upper surface thereof is exposed to the bottom surface of each contact hole CH10. The depth of over etching mentioned here is corresponding to the height h in the equation (2).

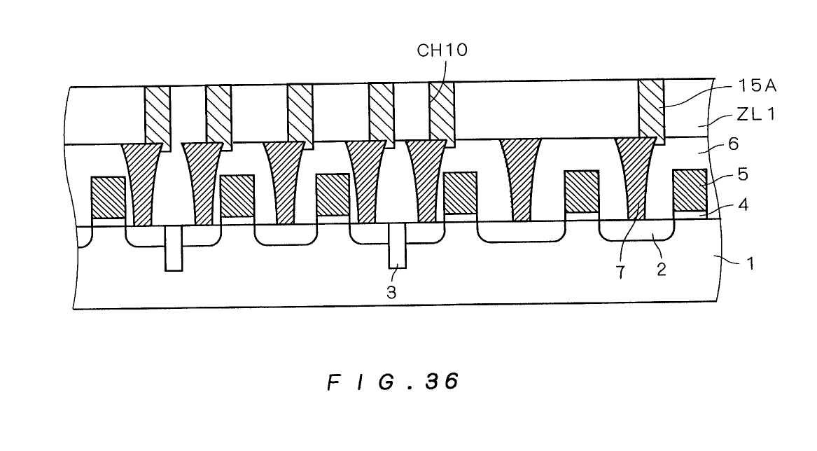

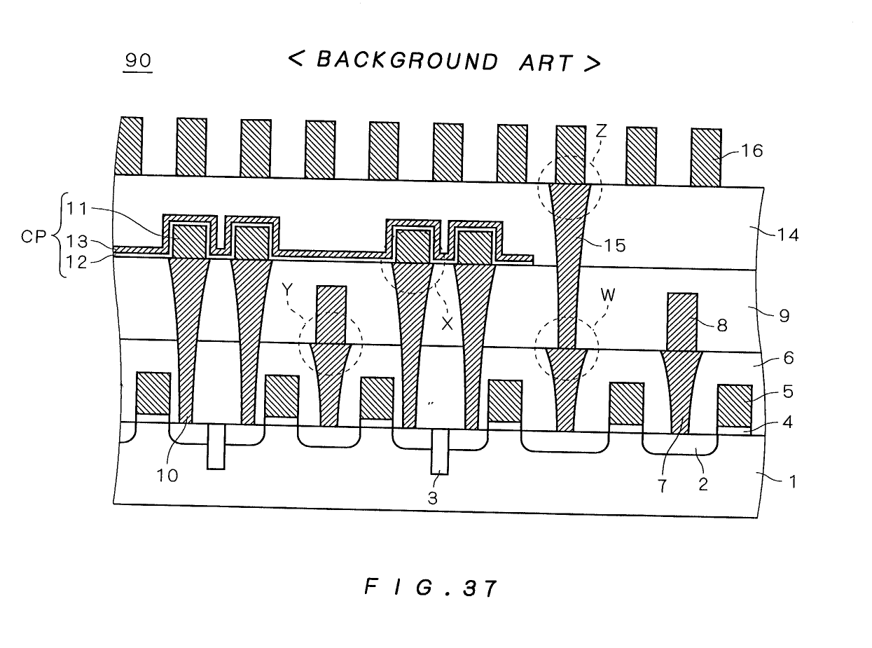

Next, in the steps illustrated in FIG. 35, layers consisting of Ti and TiN are sequentially formed all over the main surface of the insulating film ZL1 by using the method such as sputtering. On these layers, a layer consisting of W is further formed by using the CVD method, to constitute a multilayered conductive layer MCL1. The contact holes CH10 are then filled with the multilayered conductive layer MCL1.

Thereafter, in the steps illustrated in FIG. 36, the multilayered conductive layer MCL1 is planarized by using the technique such as CMP so that the multilayered conductive layer MCL1 on the insulating film ZL1 is removed. The plurality of contact plugs 15A are thereby formed by filling the plurality of contact holes CH10 with the multilayered conductive layer. After this, the insulating film ZL1 is removed. Here, the method of planarizing the multilayered conductive layer MCL1 is not limited to CMP. The alternative method such as etch back is applicable.

After this, the interlayer insulating film 22 is formed in such a manner that the upper surfaces of the contact plugs 15A remain exposed. Thereafter, layers consisting of Ti, TiN and Al are sequentially formed all over the main surface of the interlayer insulating film 22 by using the method such as sputtering. These layers are patterned by means of photolithography and dry etching to form the plurality of metal wires 16 each having connection to the upper surface of each of the plurality of contact plugs 15A as illustrated in FIG. 31.

The method of forming the metal wires 16 and the material therefor are not limited to those described above. Alternatively, the metal wires 16 may be provided through damascene process for processing Cu (copper) that is obtained by plating.

In the subsequent steps, the wiring layer and passivation film are formed on the metal wires 16 to constitute the semiconductor integrated circuit 300. As these constituents are formed by the known technique conventionally used, the description thereof is omitted here.

The foregoing description has been given on the basis of the condition that each of the contact plugs 7 and 15A of a cylindrical shape has a circular shape on the upper and lower surfaces thereof. However, the shapes of the contact plugs 7 and 15A are not limited to the cylindrical shape. Each of the sections of the contact plugs 7 and 15A may be elliptical, or alternatively, of an oval shape including ends each being of a semicircle having a curvature and including center parts linearly extending such as a track in the athletics. Even when each of the contact plugs 7 and 15A has a section of either one of these shapes, the same effects can be achieved by arranging the contact plug 15A at a deviated position.

When the contact plugs 7 and 15A are not of a cylindrical shape, according to the shapes of the upper and lower surfaces of each of the plugs 7 and 15A, the cross-sectional dimensions of lines extending through the respective centers of the upper and lower surfaces of each of the contact plugs 7 and 15A in a predetermined direction can be applicable instead of the diameter of the same. Here, the amount of deviation of the contact plug 15A is determined by using these cross-sectional dimensions.

While the invention has been shown and described in detail, the foregoing description is in all aspects illustrative and not restrictive. It is therefore understood that numerous modifications and variations can be devised without departing from the scope of the invention.

What is claimed is:

1. A semiconductor integrated circuit, comprising:
a semiconductor substrate;
an interlayer insulating film formed on said semiconductor substrate;
a conductive layer formed on said interlayer insulating film; and
a contact plug penetrating through said interlayer insulating film and having electrical connection to said conductive layer,
wherein said contact plug protrudes from an upper main surface of said interlayer insulating film by a predetermined height,
said conductive layer has a dimension in a first direction smaller than a cross-sectional dimension of an upper surface of said contact plug in said first direction and a dimension in a second direction perpendicular to said first direction larger than a cross-sectional dimension of said upper surface of said contact plug in said second direction, and
said conductive layer is arranged in contact with said contact plug in such a manner that a center of said conductive layer in said dimension in said first direction is located at a position deviated from a center of said upper surface of said contact plug.

2. The semiconductor integrated circuit according to claim 1, wherein
said conductive layer is arranged in such a manner that one edge of said conductive layer in said dimension in said first direction is located outside an edge of said upper surface of said contact plug.

3. The semiconductor integrated circuit according to claim 1, wherein
said contact plug has a cylindrical shape, and
said cross-sectional dimensions of said upper surface of said contact plug in said first and second directions are corresponding to a diameter of said contact plug.

4. The semiconductor integrated circuit according to claim 3, wherein
said predetermined height of protrusion of said contact plug is 0.16 times or more said diameter of said upper surface of said contact plug.

5. The semiconductor integrated circuit according to claim 3, wherein
an amount of deviation of said center of said conductive layer in said dimension in said first direction from said center of said upper surface of said contact plug is 0.5 times or less said diameter of said upper surface of said contact plug.

6. The semiconductor integrated circuit according to claim 1, wherein
said interlayer insulating film includes a recessed portion of a predetermined depth provided in a periphery of said contact plug, said recessed portion having a shape conforming to a shape of said conductive layer in a plan view,
said conductive layer is arranged in such a manner that a part of said conductive layer is inserted into said recessed portion, and
said predetermined depth of said recessed portion is corresponding to said predetermined height of protrusion of said contact plug.

7. The semiconductor integrated circuit according to claim 1, wherein
said conductive layer is a storage node electrode of a capacitor formed on said interlayer insulating film.

8. The semiconductor integrated circuit according to claim 7, wherein
said storage node electrode is of a shape in a plan view including a constricted part having a diameter smaller than a diameter of a part other than said constricted part, and
said storage node electrode is arranged in such a manner that said constricted part is located on said upper surface of said contact plug.

9. The semiconductor integrated circuit according to claim 1, wherein
said conductive layer is a wiring layer provided on said interlayer insulating film.

10. The semiconductor integrated according to claim 9, wherein
said wiring layer is of a shape in a plan view having different width dimensions, and
said wiring layer is arranged in such a manner that said upper surface of said contact plug holds a part of said wiring layer provided thereon having a width dimension smaller than said cross-sectional dimension of said upper surface of said contact plug in said first direction.

11. A semiconductor integrated circuit, comprising:
a semiconductor substrate;
an interlayer insulating film formed on said semiconductor substrate; and
a lower contact plug and an upper contact plug vertically arranged in said interlayer insulating film, said lower contact plug and said upper contact plug being connected to each other,
wherein a lower surface of said upper contact plug has a cross-sectional dimension in a first direction smaller than a cross-sectional dimension of an upper surface of said lower contact plug in said first direction, and
a center of said lower surface of said upper contact plug is located at a position deviated from a center of said upper surface of said lower contact plug so that connection is established between a part of said upper contact plug and a side surface of said lower contact plug.

12. The semiconductor integrated circuit according to claim 11, wherein
each of said lower and upper contact plugs have a cylindrical shape,
said cross-sectional dimension of said lower surface of said upper contact plug in said first direction and said cross-sectional dimension of said upper surface of said lower contact plug in said first direction are corresponding to respective diameters of said upper contact plug and said lower contact plug, and
an amount of deviation of said center of said lower surface of said upper contact plug from said center of said upper surface of said lower contact plug is 0.5 times or less said diameter of said upper surface of said lower contact plug.

13. A method of manufacturing a semiconductor integrated circuit, comprising the steps of:
(a) forming an interlayer insulating film on a semiconductor substrate;
(b) forming a contact plug penetrating through said interlayer insulating film to reach said semiconductor substrate;
(c) locating said contact plug so that said contact plug protrudes from an upper main surface of said interlayer insulating film by a predetermined height; and
(d) forming a conductive layer on said contact plug having a dimension in a first direction smaller than a cross-sectional dimension of an upper surface of said contact plug in said first direction and a dimension in a second direction perpendicular to said first direction larger than a cross-sectional dimension of said upper surface of said contact plug in said second direction,
wherein said step (d) further comprises the step of locating said conductive layer so that said conductive layer is in contact with said contact plug in such a manner that a center of said conductive layer in said dimension in said first direction is at a position deviated from a center of said upper surface of said contact plug.

14. The method of manufacturing a semiconductor integrated circuit according to claim 13, wherein
said step (c) further comprises the step of making a depression in a periphery of said contact plug by a predetermined depth to form a recessed portion therein, said recessed portion having a shape conforming to a shape of said conductive layer in a plan view,
said step (d) further comprises the step of locating said conductive layer so that a part of said conductive layer is inserted into said recessed portion, and
said predetermined depth of said recessed portion is corresponding to said predetermined height of protrusion of said contact plug.
